(19) United States
(12) Patent Application Publication
(10) Pub. No.: US 2006/0211176 A1
(43) Pub. Date: Sep. 21, 2006

(54) Manufacturing method for physical quantity sensor using lead frame and bonding device therefor

(75) Inventors: Kenichi Shirasaka, Hamamatsu-shi (JP); Hiroshi Saitoh, Iwata-shi (JP)

Correspondence Address: DICKSTEIN SHAPIRO MORIN & OSHINSKY LLP, 1177 AVENUE OF THE AMERICAS (6TH AVENUE), 41 ST FL., NEW YORK, NY, 10036-2714, US

(73) Assignee: Shiga International, Tokyo (JP)

(21) Appl. No.: 11/368,848

(22) Filed: Mar. 7, 2006

(30) Foreign Application Priority Data
Mar. 9, 2005 (JP) P2005-066183
Mar. 28, 2005 (JP) P2005-091614
Jun. 16, 2005 (JP) P2005-176221
Jul. 6, 2005 (JP) P2005-197439

(51) Int. Cl. H01L 21/00; H01L 23/48; H01L 23/52; H01L 29/40

(52) U.S. Cl. 438/123; 257/770

(57) ABSTRACT

A physical quantity sensor is produced using a lead frame having at least one stage for mounting a physical quantity sensor chip and a frame having leads, wherein the physical quantity sensor chip is inclined with respect to the frame. A bonding device performs wire bonding so as to electrically connect the physical quantity sensor chip and leads, which are respectively located perpendicular to a capillary for discharging wires. The bonding device includes a wedge tool having a first planar surface for holding one ends of wires with leads and a second planar surface for holding the other ends of wires with the physical quantity sensor chip. The lead frame includes interconnection leads, having shape memory alloys, for interconnecting the stage and frame together. The physical quantity sensor chip can be mounted on the stage via an inclination member having a wedge shape.

### BACKGROUND OF THE INVENTION

1. Field of the Invention

The present invention relates to manufacturing methods for physical quantity sensors using lead frames, which detect physical quantities such as bearings, magnetism, gravitation, and acceleration. The present invention also relates to bonding devices for use in manufacturing of physical quantity sensors.

This application claims priorities on Japanese Patent Applications Nos. 2005-66183, 2005-91614, 2005-176221, and 2005-197439, the contents of which are incorporated herein by reference.

2. Description of the Related Art

Recently, portable terminal devices such as cellular phones having GPS (Global Positioning System) functions for displaying users' positional information have been developed and sold in the open market. In addition to GPS functions, they also have functions for precisely detecting geomagnetism and acceleration so as to detect bearings and moving directions of users in a three-dimensional space.

In order to realize the aforementioned functions, it is necessary for portable terminal devices to have physical quantity sensors such as magnetic sensors and acceleration sensors. In order to detect bearings and acceleration in a three-dimensional space by use of physical quantity sensors, it is necessary that physical quantity sensor chips be attached onto slanted planes.

Various types of physical quantity sensors have been developed, and one example thereof is designed as a magnetic sensor for detecting magnetism and is not attached to a slanted plane. This magnetic sensor includes a pair of magnetic sensor chips both mounted on the surface of a substrate, i.e., a first magnetic sensor chip (or a physical quantity sensor chip) having sensitivities to an external magnetic field in two directions (i.e., X-axis and Y-axis directions perpendicular to each other) lying in parallel to the surface, and a second magnetic sensor chip having a sensitivity to an external magnetic field in another direction (i.e., a Z-axis direction) lying perpendicular to the surface.

Based on components of magnetism detected by the magnetic sensor chips, the magnetic sensor measures vectors representing components of magnetism in a three-dimensional space.

The aforementioned magnetic sensor is attached to a substrate in such a way that the second magnetic sensor chip is vertically mounted on the surface of the substrate. This increases the overall thickness (i.e., the height in the Z-axis direction) of the magnetic sensor. In order to minimize the thickness, it is preferable that physical quantity sensors be attached to slanted planes as disclosed in various documents such as Japanese Unexamined Patent Application Publication Nos. H09-292408, 2002-156204, and 2004-128473.

One example of the aforementioned physical quantity sensor is disclosed in Japanese Unexamined Patent Application Publication No. H09-292408, which teaches an acceleration sensor. This acceleration sensor having a cantilever beam structure is designed such that an acceleration sensor chip thereof is inclined to a substrate; therefore, even though a sensor package thereof is mounted on the surface of the substrate, it is possible to maintain high sensitivities in prescribed axial directions in correspondence with inclination, and it is possible to reduce sensitivities in other axial directions including prescribed directions lying on the surface of the substrate.

As described above, when physical quantity sensors include physical quantity sensor chips mutually inclined toward each other, it is possible to minimize the overall thickness thereof so as to realize flat shapes and to demonstrate various advantages due to inclination of chips. Hence, they will come to form a mainstream technology in the future.

An example of the aforementioned physical quantity sensor is shown in FIG. 45, in which a physical quantity sensor 380 includes a pair of physical quantity sensor chips 381 and 382 having numerous leads 383 for establishing electric connections with an external device, both of which are integrally fixed and encapsulated in a resin mold section 384. Both the physical quantity sensor chips 381 and 382 are inclined to a lower surface (or a bottom) 384a of the resin mold section 384.

In the manufacturing of the aforementioned physical quantity sensor 380, stages 385 and 386 of a lead frame are respectively inclined by press working; then, the physical quantity sensor chips 381 and 382 are mounted on the stages 385 and 386. Thereafter, wires 387 are provided to perform wire bonding so as to establish electric connections between pads, which are formed on the surfaces of the physical quantity sensor chips 381 and 382, and the leads 383.

Wire boding is performed in such a way that a capillary is positioned perpendicular to the surfaces of the physical quantity sensor chips 381 and 382 respectively.

In the wire bonding, a camera is used to recognize the surface patterns of the physical quantity sensor chips 381 and 382 so as to perform positional correction with respect to the physical sensor chips 381 and 382 through the comparison between the recognition results and the pre-stored patterns. Wire bonding is conventionally performed such that a capillary lying coaxial with the aforementioned camera is arranged perpendicular to the surfaces of the physical quantity sensor chips 381 and 382. This is disclosed in the document entitled “ASIC Packaging Technology Handbook”, first Edition, written by Susumu Kayama and four other members and published by Science Form Co. Ltd., Dec. 25, 1992, pp. 267-272.

That is, wire bonding for manufacturing the physical quantity sensor 380 is performed in accordance with the following steps.

First, a lead frame is entirely inclined so that the physical quantity sensor chip 381, within the two physical quantity sensor chips 318 and 382 inclined with respect to each other, is held horizontally; then, wiring bonding is performed on the physical quantity sensor chip 381.

After the aforementioned step, the lead frame is subjected to transportation such that it is stored in a magazine stocker, or it is moved toward another bonding station. The lead frame is entirely inclined so that the other physical sensor chip 382 is held horizontally; then, wire bonding is performed on the physical quantity sensor chip 382.

As described above, in the manufacturing of the physical quantity sensor 380, wire bonding is performed not in a direction perpendicular to the surfaces of the leads 283 but is performed in a slanted direction. This causes a problem in that adhesion between the leads 383 and wires 387 is degraded.

In order to solve the aforementioned problem, it is necessary to additionally form bonding portions, which improve the adhesion by reinforcement, on bonded portions at which the wires 387 are bonded with the leads 383. This causes a difficulty in reducing the overall manufacturing cost of the physical quantity sensor 380.

In addition, wire bonding is performed in such a way that the tip end of a capillary for discharging the wire 387 is pressed against the lead 383 and the bonding pad, which are then applied with heat and ultrasonic vibration so that both ends of the wire 387 are respectively bonded onto the lead 383 and the bonding pad. Normally, wire bonding is performed in accordance with a ball bonding method; hence, it is preferable that the capillary be located perpendicular to the surface of the lead 383.

In the above, both the surface of the stage and the surface of the physical quantity sensor chip are inclined with respect to the surface of the lead. Therefore, even though wire bonding is performed in accordance with the ball bonding method, a reduction may occur in a bonding strength applied to the bonding pad of the physical quantity sensor chip. In order to avoid such a reduction of the bonding strength, it is necessary to increase the overall area of the bonding pad. However, this causes a difficulty in reducing the overall size of the physical quantity sensor chip.

There is a possibility that the inclination angles of the stages may be altered during the transportation of a lead frame after the stages are inclined. The sensitivity of a physical quantity sensor will be degraded when the inclination angles of the stages are altered during manufacturing thereof, whereby it becomes difficult to detect bearings and acceleration in a three-dimensional space with a high precision.

In order to incline stages with respect to a frame during manufacturing of a physical quantity sensor, a lead frame may likely be partially deformed, thus causing the inclination angles of the stages to be unexpectedly altered. This may degrade the precision of setting inclination angles to physical quantity sensor chips; and this may cause difficulty for a physical quantity sensor to accurately detect bearings and acceleration in a three-dimensional space.

### SUMMARY OF THE INVENTION

It is an object of the invention to provide a manufacturing method for a physical quantity sensor, in which adhesion between leads and wires is improved without forming additional bonding portions by use of a bonding device.

It is another object of the invention to provide a manufacturing method for a physical quantity sensor, in which bonding strength between a wire and a bonding pad of a physical quantity sensor chip is improved by use of a bonding device.

Basically, the present invention is directed to a manufacturing method for a physical quantity sensor that is produced using a lead frame having at least one stage for mounting a physical quantity sensor chip and a frame having a plurality of leads surrounding the stage, and the manufacturing method includes an adhesion step for adhering the physical quantity sensor chip on the stage that is inclined with respect to the frame, a wiring step for performing wire bonding using wires so as to electrically connect the physical quantity sensor chip and the leads respectively by means of a bonding device, and a positioning step for establishing prescribed positioning so as to allow the wires to be precisely bonded onto the physical quantity sensor chip and the leads by controlling a positional relationship between the lead frame and the bonding device.

In a first aspect of the present invention adapted to a physical quantity sensor that is produced using a lead frame having at least one stage for mounting a physical quantity sensor chip and a frame having a plurality of leads surrounding the stage, a manufacturing method for the physical quantity sensor includes an adhesion step for adhering the physical quantity sensor chip on the stage that is inclined with respect to the frame and a wiring step for performing wire bonding using wires so as to electrically connect the surface of the physical quantity sensor chip, which is inclined with respect to the frame, and the surfaces of the leads respectively. When the wire bonding is performed, the lead frame is pivotally rotated so as to locate the surface of the physical quantity sensor chip and the surfaces of the leads perpendicular to a capillary for discharging the wires. Specifically, when one end of a wire is bonded onto a bonding pad of the physical quantity sensor chip, the lead frame is pivotally rotated so as to locate the surface of the physical quantity sensor chip perpendicular to the capillary. When the other end of the wire is bonded onto the surface of a lead, the lead frame is pivotally rotated so as to locate the surface of the lead perpendicular to the capillary. Thus, it is possible to press both ends of the wire discharged from the capillary toward the surface of the physical quantity sensor chip and the surface of the lead respectively.

In the above, a bonding device including a base, an instrument, and a capillary is used to perform wire bonding with respect to a thin metal plate having a plurality of lead frames. The instrument is equipped with the base and pivotally rotates about a reference axial line, which is laid in parallel with the base, wherein the instrument supports the thin metal plate so as to hold the stage being inclined with respect to the frame. The capillary performs wire bonding using wires so as to electrically connect the surface of the physical quantity sensor chip and the surfaces of the leads respectively. The capillary is arranged opposite to the surface of the base with a prescribed angle therebetween. When the instrument pivotally rotates, the surface of the physical quantity sensor chip and the surfaces of the leads are respectively located perpendicularly to the capillary. Specifically, the bonding device operates as follows:

First, the thin metal plate is set to the instrument of the bonding device. Then, the instrument and the thin metal plate pivotally rotate about the reference axial line so as to locate the surface of the physical quantity sensor chip perpendicular to the capillary. The tip end of the capillary is brought into contact with the surface of the physical quantity sensor chip, so that one end of a wire discharged from the capillary is bonded onto the surface of the physical quantity sensor chip. While the capillary is continuously discharging the wire, the capillary is separated from the surface of the physical quantity sensor chip. Then, the instrument and the thin metal plate pivotally rotate again so as to locate the surface of a lead perpendicular to the capillary. The tip end of the capillary is brought into contact with the surface of the lead, so that the other end of the wire is bonded onto the surface of the lead.

As described above, both ends of a wire bridged between the physical quantity sensor chip and the lead are strongly pressed against the surface of the physical quantity sensor chip and the surface of the lead respectively; hence, it is possible to avoid a reduction of adhesion therebetween. That is, no bonding portion is required to improve the adhesion by reinforcement. Thus, it is possible to reduce the overall cost for manufacturing the physical quantity sensor.

In a second aspect of the present invention, a manufacturing method for a physical quantity sensor includes a preparation step, a stage inclination step, an adhesion step, and a wiring step. In the preparation step, there is provided a lead frame having at least one stage for mounting a physical quantity sensor and a frame having a plurality of leads surrounding the stage. In the stage inclination step, the stage is inclined with respect to the frame. In the adhesion step, the physical quantity sensor chip is adhered onto the surface of the stage. In the wiring step, electric connections are established using wires between the surface of the physical quantity sensor, which is inclined with respect to the frame, and the surfaces of the leads respectively in accordance with a wedge bonding method. Specifically, a wedge tool for use in the wiring step is positioned in parallel with the surface of the physical quantity sensor chip and the surfaces of the leads respectively so that the wires are held between the surface of the physical quantity sensor chip and the surfaces of the leads respectively. In the wiring step, when one ends of the wires join bonding pads formed on the surface of the physical quantity sensor chip, they are held between one planar surface of the wedge tool and the surface of the physical quantity sensor chip; and when the other ends of the wires join the leads, they are held between another planar surface of the wedge tool and the surfaces of the leads respectively. This assures both ends of the wires to be uniformly pressed against the surface of the physical quantity sensor chip and the surfaces of the leads respectively.

In the above, a bonding device is used to establish electric connections using wires in accordance with a wedge bonding method with respect to the aforementioned physical quantity sensor, wherein it includes a base for mounting the lead frame, and a wedge tool that can be moved relative to the base and that supplies the wires for establishing electric connections between the surface of the physical quantity sensor chip inclined with respect to the frame and the surfaces of the leads respectively. The wedge tool has a first planar surface, which is formed in parallel with the surfaces of the leads so as to hold one ends of the wires therebetween, and a second planar surface, which is formed in parallel with the surface of the physical quantity sensor chip so as to hold the other ends of the wires therebetween. The bonding device performs wire bonding between the physical quantity sensor chip and the leads as follows:

First, the lead frame in which the physical quantity sensor chip is mounted on the surface of the stage inclined with respect to the frame is mounted on the base of the bonding device. Then, one ends of wires discharged from the wedge tool are held between the second planar surface of the wedge tool and the bonding pads formed on the surface of the physical quantity sensor chip, wherein heat and ultrasonic vibration are applied to one ends of wires, which thus firmly join the bonding pads. Thereafter, while the wedge tool is continuously discharging the wires therefrom, it is moved from the surface of the physical quantity sensor chip to the surfaces of the leads. The other ends of the wires discharged from the wedge tool are held between the first planar surface of the wedge tool and the surfaces of the leads, wherein heat and ultrasonic vibration are applied to the other ends of the wires, which thus firmly join the surfaces of the leads.

It is possible to reverse the bonding order such that wires firstly join the leads, and then they join the bonding pads of the physical quantity sensor chip. That is, one ends of the wires join the leads by use of the first planar surface of the wedge tool; and then the other ends of the wires join the bonding pads of the physical quantity sensor chip by use of the second planar surface of the wedge tool.

In addition, the first and second planar surfaces of the wedge tool are partially recessed to form guide channels for guiding wires, which are elongated along the first and second planar surfaces respectively. That is, even though the wedge tool moves between the physical quantity sensor chip and the leads, the wires discharged from the wedge tool can be reliably guided by way of the guide channels along the first and second planar surfaces. This assures that the wires are pressed against the bonding pads and the surfaces of the leads by means of the first and second planar surfaces of the wedge tool. The wires are precisely positioned relative to the first and second planar surfaces of the wedge tool by means of the guide channels. This makes it possible to easily establish the prescribed positioning with respect to the wires relative to the bonding pads and the leads by simply adjusting the position of the wedge tool moved relative to the bonding pads and the leads.

Furthermore, the wedge tool is moved in a longitudinal direction of the guide channels in proximity to the surface of the physical quantity sensor chip and the surfaces of the leads respectively. That is, when the wedge tool is moved from the physical quantity sensor chip to the leads, wires discharged from the wedge tool are guided via the guide channels. Since the moving direction of the wedge tool substantially matches the longitudinal direction of the guide channels, it is possible to avoid the occurrence of a mechanical stress, which may occur when the moving direction of the wires guided by the guide channels differs from the moving direction of the wedge tool. Since the opposite ends of the wires join the physical quantity sensor chip and the leads respectively, the mechanical stress may increase remarkably when the moving direction of the wires guided by the guide channels differs from the moving direction of the wedge tool in proximity to the physical quantity sensor chip and the leads. It is possible to avoid the occurrence of such a large mechanical stress on the wires by making the moving direction of the wedge tool substantially match the longitudinal direction of the guide channels in proximity to bonding portions.

In a third aspect of the present invention, a manufacturing method for a physical quantity sensor includes a preparation step, a stage inclination step, an adhesion step, a wiring step, and a re-inclination step. In the preparation step, there is provided a lead frame, which is produced using a thin metal plate and includes at least one stage for mounting a physical quantity sensor chip, a frame having a plurality of leads surrounding the stage, and a plurality of interconnection leads, each including a shape memory alloy, for interconnecting the stage and the frame together. In the stage inclination step, the interconnection leads are heated and thus deformed at a restoration temperature of the shape memory alloy, thus allowing the stage to be inclined with respect to the frame by a prescribed angle. In the adhesion step, the physical quantity sensor chip is adhered onto the stage. In the wiring step, the physical quantity sensor chip is electrically connected to the leads respectively. In the re-inclination step, the interconnection leads are heated again at the restoration temperature of the shape memory alloy, thus inclining the stage by the prescribed angle with respect to the frame. That is, by simply performing the re-inclination step for heating the interconnection leads up to the restoration temperature of the shape memory alloy after the adhesion step and wiring step, it is possible to reliably incline the stage for mounting the physical quantity sensor chip by the prescribed angle with respect to the frame. This noticeably improves a precision of setting the inclination angle to the physical quantity sensor chip even though an external force is exerted on the stage whose inclination angle is thus varied with respect to the frame during the transportation of the lead frame, for example.

It is possible to further introduce a planation step between the stage inclination step and the adhesion step. In the planation step, the interconnection leads are subjected to plastic deformation by way of press working, so that the stage is positioned planar with respect to the frame. That is, the stage is temporarily arranged to be planar with respect to the frame in the adhesion step and wiring step. This makes it easy to mount the physical quantity sensor chip onto the stage and to electrically connect the physical quantity sensor chip to the leads.

In the aforementioned lead frame, each of the interconnection leads includes a shape memory alloy; alternatively, a shape memory alloy member is attached to each of the interconnection leads. After the physical quantity sensor chip is adhered onto the stage and after the physical quantity sensor chip is electrically connected to the leads, the inclination angle of the stage for mounting the physical quantity sensor chip can be restored by simply heating the interconnection leads up to the restoration temperature of the shape memory alloy. That is, it is possible to improve a precision of setting the inclination angle to the physical quantity sensor chip even though an external force is exerted on the stage whose inclination angle is altered during the transportation of the lead frame or before the adhesion step and wiring step are completed. In other words, the stage is temporarily positioned planar with respect to the frame after the stage inclination step; hence, it is possible to easily perform the adhesion step and wiring step. The shape memory alloy is not necessarily formed entirely over the interconnection lead but is formed partially in the interconnection lead; hence, it is possible to reduce the overall cost for manufacturing the lead frame.

In a fourth aspect of the present invention, a physical quantity sensor includes at least one stage, at least one physical quantity sensor chip, a plurality of leads that are arranged to surround the stage and that are electrically connected to the physical quantity sensor chip, at least one inclination member having a wedge shape, which is adhered onto the surface of the stage, and on which the physical quantity sensor chip is adhered, and a package for integrally fixing the stage, physical quantity sensor chip, inclination member, and leads therein. Since the physical quantity sensor chip and stage are mutually adhered together via the inclination member, it is possible to easily realize the physical quantity sensor chip being inclined by a prescribed inclination angle with respect to the stage. This improves the precision for setting the prescribed inclination angle to the physical quantity sensor chip. In contrast to the conventional technology, this does not require a step for deforming a lead frame; hence, it is possible to improve the efficiency in manufacturing the physical quantity sensor.

In the above, the inclination member is formed using a wedge base member in which an adhesion layer is formed to cover the bottom and slope thereof. Since the physical quantity sensor chip and stage are mutually adhered together by means of the adhesive layer, the wedge base member can be formed using a hard material not easily deformed plastically. This further improves the precision for setting the prescribed inclination angle to the physical quantity sensor chip.

A manufacturing method for the aforementioned physical quantity sensor includes a preparation step, an adhesion step, and a wiring step. In the preparation step, there is provided a lead frame formed using a thin metal plate, which includes at least one stage, a frame having a plurality of leads surrounding the stage, and a plurality of interconnection leads for interconnecting the stage and frame together. In the adhesion step, a physical quantity sensor chip is adhered onto the stage via an inclination member having a wedge shape. In the wiring step, the physical quantity sensor chip and the leads are electrically connected with each other.

The adhesion step further includes a chip mounting step and a member mounting step. In the chip mounting step, the physical quantity sensor chip is mounted on the slope of the inclination member. In the member mounting step, the inclination member mounting the physical quantity sensor chip is mounted onto the surface of the stage. This simplifies the manufacturing in that the inclination member on which the physical quantity sensor chip is mounted on the slope is simply mounted on the surface of the stage, which is horizontally held, thus realizing the prescribed inclination angle with ease. Alternatively, the inclination member is mounted on the surface of the stage in the member mounting step; and the physical quantity sensor chip is mounted on the slope of the inclination member in the chip mounting step. In this case, the aforementioned parts of the physical quantity sensor can be easily assembled together in that the inclination member and physical quantity sensor chip are sequentially mounted on the surface of the stage.

In the above, the inclination member has an adhesive layer having a thermosetting property, which is adhered to the physical quantity sensor chip and the stage respectively; and the adhesive layer is heated and hardened after the inclination member mounting the physical quantity sensor chip is mounted on the surface of the stage. This makes it possible to simultaneously heat the prescribed portion of the adhesive layer directly brought into contact with the physical quantity sensor chip and the other portion of the adhesive layer directly brought into contact with the stage at the same timing, so that the physical quantity sensor chip and stage are firmly adhered to the inclination by way of the hardening of the adhesive layer. This improves the efficiency in manufacturing the physical quantity sensor.

Alternatively, the inclination member has an adhesion layer having a thermosetting property, which is adhered to the physical quantity sensor chip and the stage respectively; and the inclination member mounting the physical quantity sensor chip is mounted on the surface of the stage which is heated in advance, so that the adhesive layer is heated and hardened by use of heat of the stage. Since the stage is heated in advance, the adhesive layer can be easily heated and hardened just after the inclination member is mounted on the stage. This realizes rapid adhesion between the physical quantity sensor chip, stage, and inclination member. Incidentally, the prescribed portion of the adhesive layer directly brought in contact with the physical quantity sensor chip is positioned slightly apart from the surface of the stage by the intervention of the inclination member and therefore needs a longer time for adhesion and hardening compared with the other portion of the adhesive layer directly brought into contact with the stage. In other words, after the inclination member is mounted on the stage being heated, the physical quantity sensor chip can be reliably mounted on and adhered to the slope of the inclination member because the prescribed portion of the adhesive layer is not hardened rapidly.

Furthermore, before the physical quantity sensor chip is mounted on the slope of the inclination member, the physical quantity sensor chip can be inclined in advance to be parallel to the slope of the inclination member. Specifically, the physical quantity sensor chip is attached to a collet by way of air suction and is transported toward the slope of the inclination member in such a way that the physical quantity sensor chip is inclined to be parallel to the slope of the inclination member. That is, during the transportation, the physical quantity sensor chip is held substantially parallel to the slope of the inclination member by means of the collet. This reduces positional deviation of the physical quantity sensor chip mounted on the slope of the inclination member. In other words, the physical quantity sensor chip can be mounted on the slope of the inclination member in a stable manner; hence, it is possible to improve the precision regarding the positioning of the physical quantity sensor chip relative to the slope of the inclination member.

### BRIEF DESCRIPTION OF THE DRAWINGS

These and other objects, aspects, and embodiments of the present invention will be described in more detail with reference to the following drawings, in which:

FIG. 1 is a plan view showing a lead frame for use in manufacturing of a magnetic sensor in accordance with a first embodiment of the present invention;

FIG. 2 is a plan view showing numerous lead frames formed on a single sheet of a thin metal plate;

FIG. 3 is a side view partly in cross section for explaining a stage inclination step and a bonding step of the lead frame shown in FIG. 1;

FIG. 4 is a longitudinal cross-sectional view showing parts of a bonding device in connection with a thin metal plate having lead frames;

FIG. 5 is an enlarged cross-sectional view showing parts of an instrument included in the bonding device in connection with the thin metal plate having the lead frames;

FIG. 6A is a longitudinal cross-sectional view showing that the bonding device performs wire bonding so as to bond one ends of wires to bonding pads of a magnetic sensor chip;

FIG. 6B is a longitudinal cross-sectional view showing that the bonding device performs wire bonding so as to bond the other ends of the wires to leads;

FIG. 7 is an enlarged cross-sectional view showing that each one lead frame having magnetic sensor chips is encapsulated in a resin mold section by use of metal molds;

FIG. 8 is a plan view showing the overall layout of parts included in a magnetic sensor, which is produced using the lead frame shown in FIG. 1;

FIG. 9 is a cross-sectional view showing the magnetic sensor encapsulated in a package;

FIG. 10 is a plan view showing a lead frame for use in manufacturing of a magnetic sensor in accordance with a second embodiment of the present invention;

FIG. 11 is a longitudinal cross-sectional view showing that magnetic sensor chips are adhered to stages inclined with respect to the lead frame shown in FIG. 10;

FIG. 12 is a longitudinal cross-sectional view showing a bonding device for performing wire bonding between magnetic sensor chips and leads in the lead frame shown in FIG. 10;

FIG. 13 is an enlarged cross-sectional view showing essential parts incorporated in a tip end of a wedge tool included in the bonding device;

FIG. 14 is an enlarged cross-sectional view showing an operation of the wedge tool for supplying a wire to join a magnetic sensor chip;

FIG. 15A is an enlarged cross-sectional view showing that the wedge tool presses one end of the wire onto the surface of a lead;

FIG. 15B is an enlarged cross-sectional view showing that the wedge tool moves to become separated from the surface of the lead;

FIG. 16 is a diagrammatic plan view showing moving paths of the wedge tool from bonding pads to leads;

FIG. 17 is an enlarged cross-sectional view showing the formation of a resin mold section encapsulating magnetic sensor chips therein;

FIG. 18 is a plan view showing the overall layout of essential parts included in a magnetic sensor, which is produced using the lead frame shown in FIG. 10;

FIG. 19 is a cross-sectional view showing essential parts of the magnetic sensor;

FIG. 20 is a plan view showing a lead frame for use in manufacturing of a magnetic sensor in accordance with a first variation of the present invention;

FIG. 21 is a longitudinal cross-sectional view showing essential parts of the lead frame shown in FIG. 20;

FIG. 22 is a longitudinal cross-sectional view showing that stages are respectively inclined about axial lines L1 in the lead frame shown in FIG. 21;

FIG. 23 is a longitudinal cross-sectional view showing that wire bonding is performed so as to electrically connect magnetic sensor chips, which are forced to be planar with respect to a rectangular frame portion, and leads via wires;

FIG. 24 is a longitudinal cross-sectional view showing that the stages are inclined again with respect to the rectangular frame portion;

FIG. 25 is a longitudinal cross-sectional view showing that the lead frame having the inclined stages subjected to wire bonding is held between metal molds;

FIG. 26 is a plan view showing essential parts of the magnetic sensor produced using the lead frame shown in FIG. 20;

FIG. 27 is a longitudinal cross-sectional view showing essential parts of the magnetic sensor;

FIG. 28A is a plan view showing a modified example of a lead frame for use in manufacturing of a magnetic sensor in accordance with the first variation of the present invention;

FIG. 28B is a cross-sectional view taken along line G-G in FIG. 28A;

FIG. 29 is an enlarged cross-sectional view showing a modification of a twisting portion adapted to the lead frame;

FIG. 30 is an enlarged cross-sectional view showing a further modification of a twisting portion adapted to the lead frame;

FIG. 31 is a cross-sectional view showing essential parts of a magnetic sensor produced using the lead frame shown in FIG. 28A and 28B;

FIG. 32 is a plan view showing a lead frame for use in manufacturing of a magnetic sensor in accordance with a second variation of the present invention;

FIG. 33 is a longitudinal cross-sectional view showing essential parts of the lead frame shown in FIG. 32;

FIG. 34 is an enlarged side view showing an inclination member, which is used to attach a magnetic sensor chip onto a stage in the lead frame shown in FIG. 32;

FIG. 35 is a perspective view showing a metal mold for producing a wedge base member for use in the inclination member;

FIG. 36 is a longitudinal cross-sectional view showing a transportation step in which magnetic sensor chips are transported to and mounted on slopes of inclination members;

FIG. 37 is a longitudinal cross-sectional view showing that a magnetic sensor chip is pushed upward and attached to a suction surface of a collet;

FIG. 38 is a longitudinal cross-sectional view showing that the magnetic sensor chip attached to the suction surface of the collet by way of air suction is transported to and then mounted on the slope of the inclination member;

FIG. 39 is a longitudinal cross-sectional view showing that magnetic sensor chips and stages are adhered to slopes and bottoms of inclination members by way of heating;

FIG. 40 is a longitudinal cross-sectional view showing that the lead frame having the stages, inclination members, and magnetic sensor chips is vertically held between metal molds;

FIG. 41 is a plan view showing essential parts of a magnetic sensor produced using the lead frame shown in FIG. 32;

FIG. 42 is a longitudinal cross-sectional view showing essential parts of the magnetic sensor encapsulated in a package;

FIG. 43A is a perspective view showing that resin material is subjected to rolling using rollers having bevel wheels so as to produce inclination members having wedge shapes;

FIG. 43B is a front view showing the rollers used for rolling in FIG. 43A;

FIG. 44 is a perspective view showing that a resin material is subjected to rolling using rollers having recesses so as to produce inclination members having wedge shapes; and

FIG. 45 is a side view partly in cross section showing essential parts of a conventionally-known magnetic sensor after wire bonding.

### DESCRIPTION OF THE PREFERRED EMBODIMENTS

The present invention will be described in further detail by way of examples with reference to the accompanying drawings.

1. First Embodiment

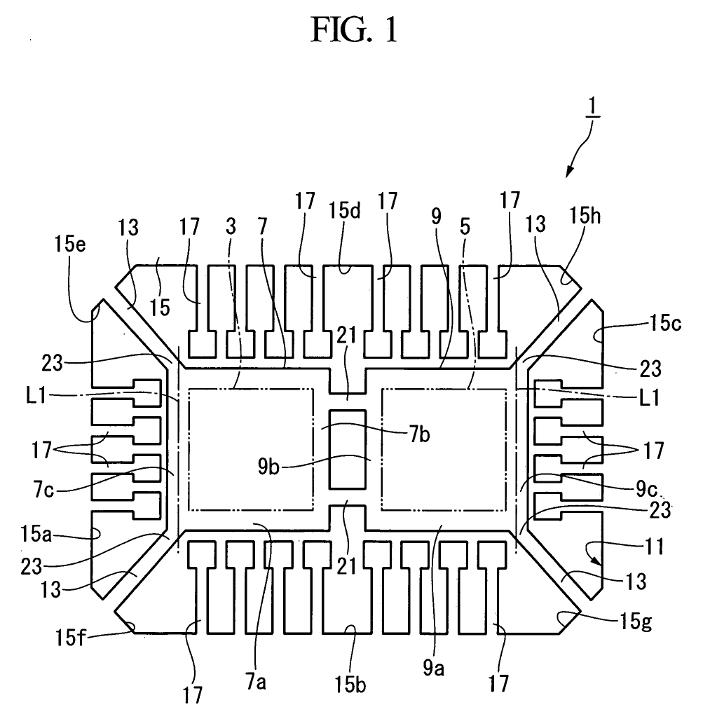

A first embodiment of the present invention will be described in detail with reference to FIGS. 1-5, 6A, 6B, and 7-9. Specifically, the first embodiment refers to a manufacturing method for a magnetic sensor and a bonding device therefor, wherein it is applied to a magnetic sensor (e.g., a physical quantity sensor) that detects the direction and magnitude of an external magnetic field by use of two magnetic sensor chips mutually inclined with respect to each other. This magnetic sensor is produced using a lead frame, which is formed by performing press working and etching on a thin metal plate composed of cupper and the like.

FIG. 1 shows a lead frame 1 that includes two stages 7 and 9 having rectangular shapes in plan view for mounting two magnetic sensor chips (or two physical quantity sensor chips) 3 and 5, a frame 11 for supporting the stages 7 and 9, and interconnection leads 13 for mutually connecting the stages 7 and 9 and the frame 11 together. The stages 7 and 9, the frame 11, and the interconnection leads 13 are all integrally formed together.

The frame 11 includes a rectangular frame portion 15 having a rectangular shape in a plan view, which surrounds the stages 7 and 9, and a plurality of leads 17, which project inwardly from four sides 15a to 15d of the rectangular frame portion 15.

The plurality of leads 17 are arranged on each of the four sides 15a to 15d of the rectangular frame portion 15 and are electrically connected to bonding pads (not shown) of the magnetic sensor chips 3 and 5.

The stages 7 and 9 have rectangular shapes on the surfaces of which the magnetic sensor chips 3 and 5 are mounted. They are positioned adjacent to each other in parallel with the sides 15b and 15d of the rectangular frame portion 15.

The stages 7 and 9 respectively have terminal ends 7b and 9b, which are positioned opposite to each other. Two stage interconnection portions 21 are formed on the terminal ends 7b and 9b so as to mutually interconnect the stages 7 and 9 together. The stage interconnection portions 21, which are easy to deform, are used to prevent the stages 7 and 9 from unexpectedly shaking or moving.

The interconnection leads 13 project inwardly from four corners 15e to 15h of the rectangular frame portion 15 toward terminal ends 7c and 9c of the stages 7 and 9. They are interconnected to side ends of the terminal ends 7c and 9c respectively. The side ends are positioned in the width direction of the stages 7 and 9 perpendicular to the coupling direction of the stages 7 and 9.

Easy-to-deform portions 23 are formed at internal ends of the interconnection leads 13 positioned close to the terminal ends 7c and 9c of the stages 7 and 9. The easy-to-deform portions 23 are easily deformable in order to rotatably incline the stages 7 and 9 about axial lines L1, which are perpendicular to the thickness direction of the rectangular frame portion 15. The axial lines L1 are perpendicular to the coupling direction of the stages 7 and 9.

The easy-to-deform portions 23 are formed using channels, which are recessed in the thickness direction of the lead frame 1 by way of photo-etching, or using cutouts which are formed by partially cutting the interconnection leads 13 in their width directions, for example. The aforementioned channels or cutouts can be formed simultaneously with the formation of the lead frame 1 using a thin metal plate.

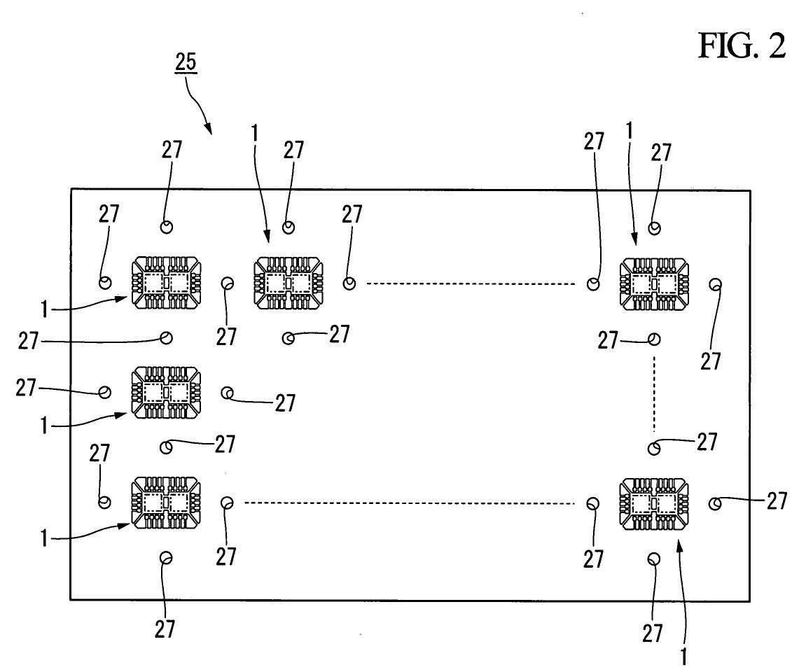

As shown in FIG. 2, numerous lead frames 1 are formed by performing press working and etching on a thin metal plate 25 composed of copper and the like. The present embodiment shows the numerous lead frames 1 on a single sheet of the thin metal plate 25. Of course, it is possible to appropriately change the number and positions of the lead frames 1 to be formed on the thin metal plate 25. In addition, through holes 27 running through in the thickness direction of the thin metal plate 25 are formed to surround the lead frames 1 respectively.

Next, a manufacturing method for a magnetic sensor using the aforementioned lead frame 1 will be described in detail.

First, there is provided the thin metal plate 25 on which the numerous lead frames 1 are formed in a preparation step. Each of the lead frames 1 is subjected to press working so that the two stages 7 and 9 are respectively inclined about the axial lines L1 with respect to the rectangular frame portion 15 in a stage inclination step.

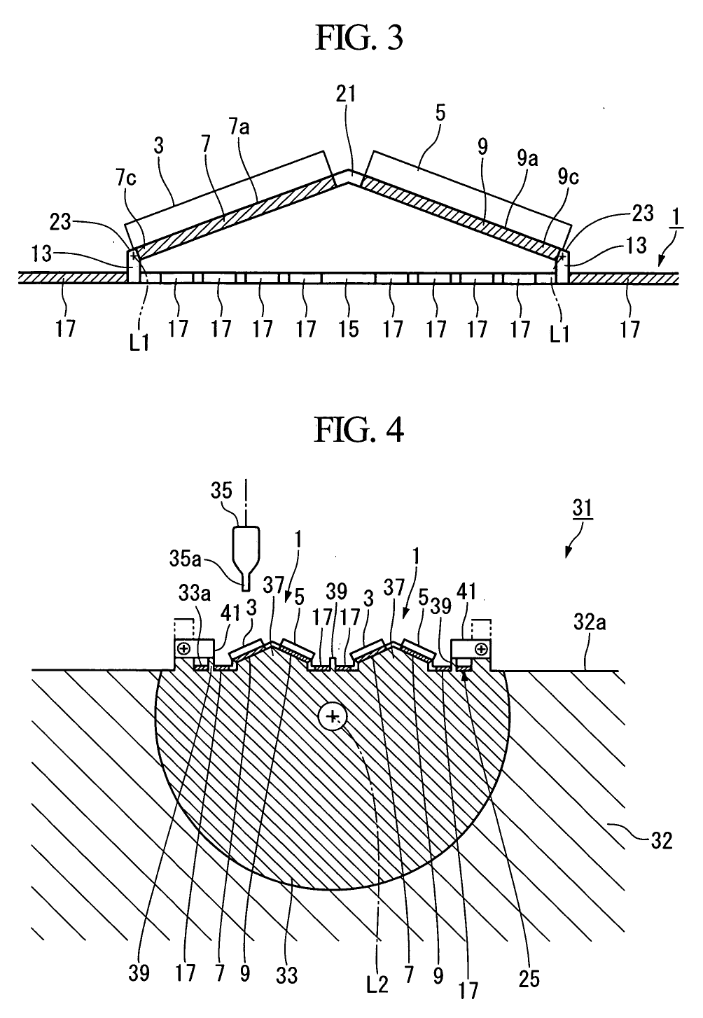

Due to the press working in the stage inclination step, the easy-to-deform portions 23 of the interconnection leads 13 and the stage interconnection portions 21 are deformed so that the stages 7 and 9 are rotatably inclined about the axial lines L1. In the stage inclination step, the terminal ends 7c and 9c of the stages 7 and 9 are shifted in position in the thickness direction of the thin metal plate 25 with respect to the rectangular frame portion 15 and the leads 17. FIG. 3 shows that the stages 7 and 9 are respectively inclined by prescribed angles with respect to the rectangular frame portion 15.

After completion of the stage inclination step, the magnetic sensor chips 3 and 5 are adhered onto surfaces 7a and 9a of the stages 7 and 9 via silver pastes in an adhesion step.

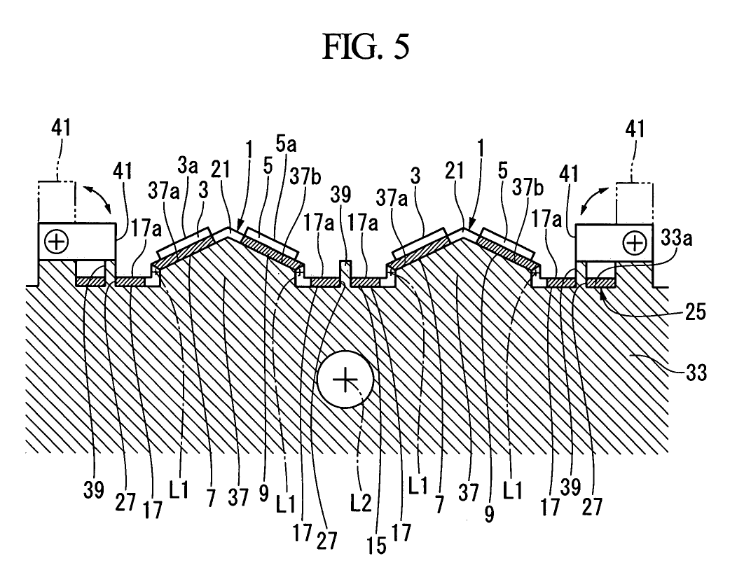

After completion of the adhesion step, as shown in FIGS. 4 and 5, a bonding device 31 is used to perform wire bonding so as to electrically connect bonding pads, which are formed on surfaces 3a and 5a of the magnetic sensor chips 3 and 5, and the leads 17 in a wiring step.

The bonding device 31 includes a base 32 having a planar surface 32a, an instrument 33 for positioning the thin metal plate 25 having numerous lead frames 1 on a surface 33a, and a capillary 35 for arranging wires between the bonding pads and the leads 17.

The instrument 33 can pivotally rotate about a reference axial line L2, which is laid in parallel with the planar surface 32a of the base 32. The reference axial line L2 is positioned substantially in parallel with the aforementioned axial lines L1 for rotatably inclining the stages 7 and 9. In the wiring step, heat and mechanical stress due to wire bonding occur; hence, it is preferable that the instrument 33 be formed using a prescribed metal having resistance against the heat and mechanical stress.

Numerous stage supports 37, the number of which matches the number of the leads frames 1 formed on the thin metal plate 25, are formed on the surface 33a of the instrument 33. In addition, numerous projections 39 to be respectively inserted into the through holes 27 of the thin metal plate 25 are formed on the surface 33a of the instrument 33. Each of the stage supports 37 has a wedge form having a pair of slopes 37a and 37b on which the stages 7 and 9 are positioned.

When the thin metal plate 25 is attached onto the instrument 33, the rectangular frame portions 15 and the leads 17 of the lead frames 1 are arranged on the surface 33a of the instrument 33; and the stages 7 and 9 are positioned on the slopes 37a and 37b of the stage supports 37. Thus, it is possible to hold the stages 7 and 9 being inclined with respect to the rectangular frame portions 15 and the leads 17.

When the rectangular frame portions 15 and the leads 17 are arranged on the surface 33a of the instrument 33, the projections 39 are respectively inserted into the through holes 27 of the thin metal plate 25; hence, it is possible to prevent the lead frames 1 from being shifted in position irrespective of the stage supports 37. That is, the instrument 33 collectively supports the stages 7 and 9, the leads 17, and the rectangular frame portions 15.

In addition, stoppers 41 are arranged in the periphery of the surface 33a of the instrument 33. The stoppers 41 are used to close the tip ends of the projections 39, which are formed in the peripheral portion of the instrument 33. Each of the stoppers 41 can rotatably move at the periphery of the instrument 33 between a position at which it comes in contact with the tip end of the projection 39, and a position at which it moves away from the tip end of the projection 39. When the stoppers 41 are brought into contact with the tip ends of the projections 39, it is possible to prevent the thin metal plate 25 from being removed from the projections 39.

The capillary 35 is directed substantially perpendicular to the planar surface 32a of the base 32. It supplies wires toward the planar surface 32a from a tip end 35a thereof. The capillary 35 can move horizontally in parallel with the planar surface 32a of the base 35, and it can also move vertically in a direction perpendicular to the planar surface 35a.

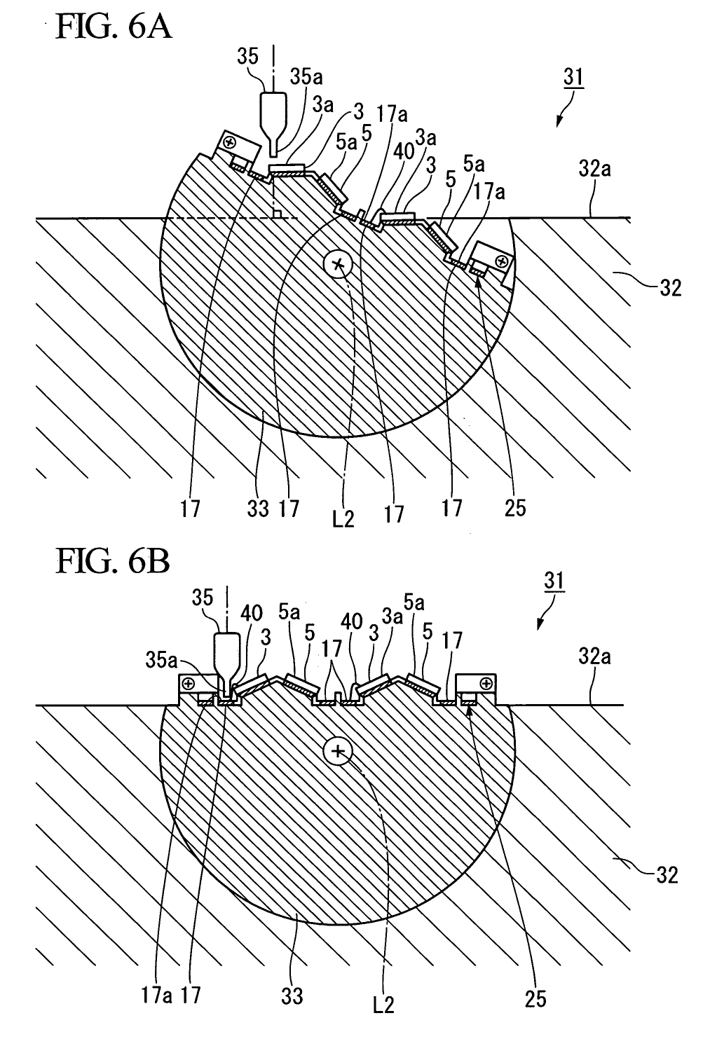

The wiring step is performed using the aforementioned bonding device 31. In the wiring step, as shown in FIGS. 6A and 6B, the instrument 33 and the thin metal plate 25 pivotally rotate about the reference axial line L2, thus making the surfaces 3a and 5a of the magnetic sensor chips 3 and 5 and surfaces 17a of the leads 17 respectively locate perpendicularly to the capillary 35.

First, as show in FIG. 6A, the instrument 33 pivotally rotates about the reference axial line L2, thus making the surface 3a of the magnetic sensor chip 3 locate perpendicularly to the capillary 35. Then, the tip end 35a of the capillary 35 is brought into contact with bonding pads formed on the surface 3a of the magnetic sensor chip 3, so that one ends of wires 40 discharged from the tip end 35a of the capillary 35 are bonded onto the bonding pads.

While the tip end 35a of the capillary 35 is continuously discharging the wires 40, the capillary 35 is separated off from the surface 3a of the magnetic sensor chip 3. Thereafter, the instrument 33 and the thin metal plate 25 pivotally rotate about the reference axial line L2 as shown in FIG. 6B, in which they are located perpendicularly to the capillary 35. Then, the tip end 35a of the capillary 35 is brought into contact with the surfaces 17a of the leads 17, so that the other ends of the wires 40 are bonded into the surfaces 17a of the leads 17.

After electric connections are established using the wires 40 between the magnetic sensor chip 3 and the leads 17, wire bonding is performed using the wires 40 so as to establish electric connections between the magnetic sensor chip 5 and the leads 17. When the capillary 35 is used to perform wire bonding using the wires 40, the instrument 33 and the thin metal plate 25 pivotally rotate so as to locate the surface 5a of the magnetic sensor chip 5 and the surfaces 17a of the leads 17 perpendicular to the capillary 35.

The aforementioned wire bonding is performed by making the surfaces 3a and 5a of the magnetic sensor chips 3 and 5 and the surfaces 17a of the leads 17 locate perpendicularly to the capillary 35. This makes it possible for the tip end 35a of the capillary 35 to press both ends of the wires 40 toward the surfaces 3a and 5a of the magnetic sensor chips 3 and 5 and the surfaces 17a of the leads 17.

In the wiring step, a positioning camera (not shown) installed in the bonding device 31 is used to establish positioning between the tip end 35a of the capillary 35 and the magnetic sensor chips 3 and 5 and the leads 17. Specifically, the positioning camera picks up images regarding the surfaces 3a and 5a of the magnetic sensor chips 3 and 5 and the surfaces 17a of the leads 17 so as to produce image data, based on which relative positional relationships between the capillary 35 and the magnetic sensor chips 3 and 5 and the leads 17 are adjusted.

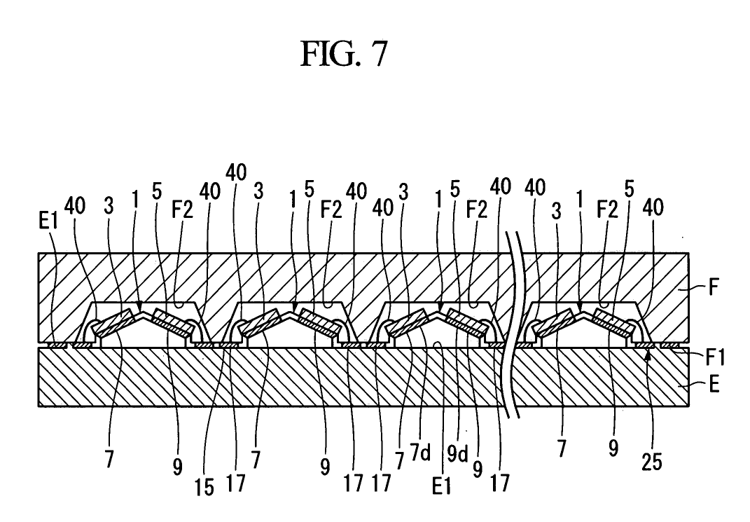

After completion of the wiring step, the thin metal plate 25 is removed from the bonding device 31; then, as shown in FIG. 7, the thin metal plate 25 is held vertically using a pair of metal molds E and F. Specifically, the lower metal mold E has a planar surface E1, on which the rectangular frame portion 15 and the leads 17 are arranged; and the upper metal mold F has a surface F1 having numerous recesses F2. When the rectangular frame portion 15 of the thin metal plate 25 is held between the metal molds E and F, each one lead frame 1 having the magnetic sensor chips 3 and 5, the stages 7 and 9, and the leads 17 is stored in each one recess F2.

Thereafter, a melted resin is injected into each one space defined by each one recess F2 of the metal mold F and the planar surface E1 of the metal mold E, so that the magnetic sensor chips 3 and 5 are enclosed in a resin mold section in a molding step.

In the molding step, the stages 7 and 9 are shifted in position in the thickness direction of the thin metal plate 25 with respect to the rectangular frame portion 15. This makes it possible for a melted resin to be easily introduced toward backsides 7d and 9d of the stages 7 and 9. As a result, it is possible to fill gaps, which are formed between the backsides 7d and 9d of the stages 7 and 9 and the planar surface E1 of the lower metal mold E, with a melted resin.

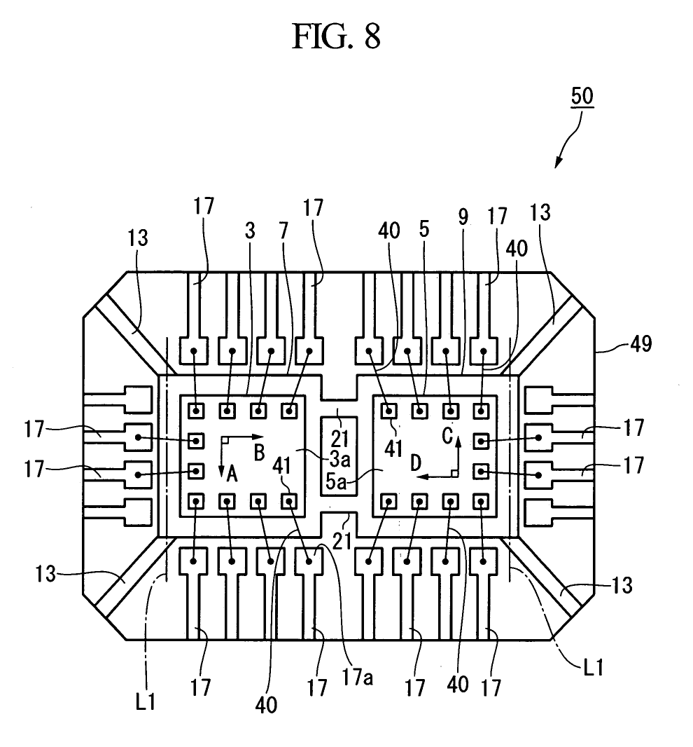

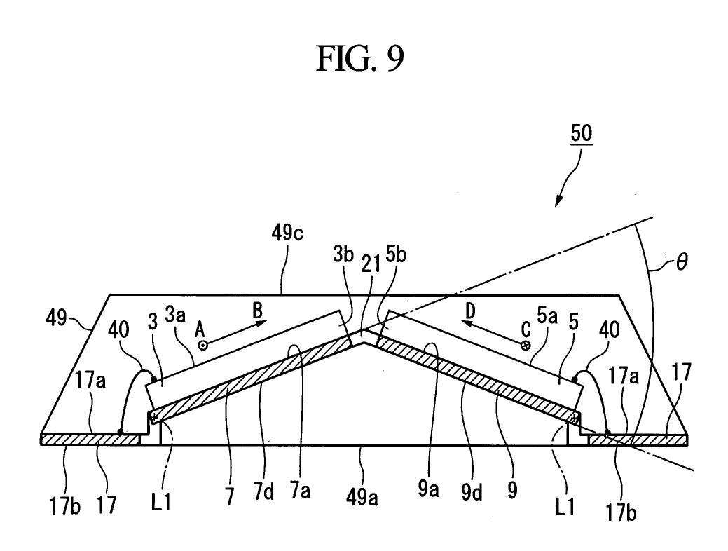

After completion of the molding step, it is possible to fix the magnetic sensor chips 3 and 5, which are mutually inclined with respect to each other, inside of a resin mold section 49 as shown in FIGS. 8 and 9. Incidentally, it is preferable that the aforementioned resin be composed of a high-fluidity material in order not to cause unexpected variations of inclination angles of the magnetic sensor chips 3 and 5 due to the resin flow.

Lastly, the rectangular frame portion 15 is cut out so as to individually separate the interconnection leads 13 and the leads 17. Thus, the manufacturing of a magnetic sensor 50 is completed.

In the magnetic sensor 50 shown in FIG. 9, the resin mold section 49 (i.e., a package) is formed to have a rectangular shape in a plan view similarly to the aforementioned rectangular frame portion 15. The leads 17 are electrically connected to the magnetic sensor chips 3 and 5 via the metal wires 40. Backsides 17b of the leads 17 are exposed to a lower surface 49a of the resin mold section 49.

Both the magnetic sensor chips 3 and 5 are embedded inside of the resin mold section 49 and are inclined with respect to the lower surface 49a of the resin mold section 49. In addition, the magnetic sensor chips 3 and 5 are positioned opposite to each other and are mutually inclined with each other by an acute angle θ, which is formed between the surface 7a of the stage 7 and the backside 9d of the stage 9 as shown in FIG. 9.

The magnetic sensor chip 3 is sensitive to two magnetic components of an external magnetic field with respect to two directions, i.e., directions A and B crossing with a right angle therebetween along the surface 3a of the magnetic sensor chip 3.

Similarly, the magnetic sensor chip 5 is sensitive to two magnetic components of an external magnetic field with respect to two directions, i.e., directions C and D crossing with a right angle therebetween along the surface 5a of the magnetic sensor chip 5.

In the above, the directions A and C are parallel to the axial lines L1, about which the stages 7 and 9 rotate, and are reverse to each other. The directions B and D are perpendicular to the axial lines L1 and are reverse to each other.

In addition, an A-B plane, which is defined in the directions A and B along the surface 3a of the magnetic sensor chip 3, crosses a C-D plane, which is defined in the directions C and D along the surface 5a of the magnetic sensor chip 5, with the acute angle θ therebetween.

The angle θ formed between the A-B plane and the C-D plane is greater than 0° and less than 90°. Theoretically, the magnetic sensor 50 is capable of three-dimensional bearings based on the geomagnetism when the angle θ is greater than 0°. In order to secure a minimum sensitivity with respect to geomagnetic vector components perpendicular to the A-B plane or the C-D plane and to calculate them with a small error, it is preferable that the angle θ be set to 20° or more. In order to further reduce the error in calculation, it is preferable that the angle θ be set to 30° or more.

For example, the magnetic sensor 50 is mounted on a substrate incorporated in a portable terminal device (not shown), which in turn displays bearings of geomagnetism detected by the magnetic sensor 50 on a display panel (not shown).

In the manufacturing method for the magnetic sensor 50 using the bonding device 31, the tip end 35a of the capillary 35 reliably presses both ends of the wires 40, which are arranged between the magnetic sensor chips 3 and 5 and the leads 17, toward the surfaces 3a and 5a of the magnetic sensor chips 3 and 5 and the surfaces 17a of the leads 17 in the wiring step. This avoids a reduction of adhesion between the wires 40 and the surfaces 3a and 5a of the magnetic sensor chips 3 and 5 and the surfaces 17a of the leads 17. In addition, the present embodiment is advantageous compared with the conventional technology because it does not need bonding portions for improving adhesion by reinforcement. Therefore, it is possible to reduce the overall manufacturing cost of the magnetic sensor 50.

The reference axial line L2 about which the instrument 33 pivotally rotates is laid substantially in parallel with the axial lines L1 about which the stages 7 and 9 rotate; hence, pivotally rotating the instrument 33 about the reference axial line L2 makes it possible that the surfaces 3a and 5a of the magnetic sensor chips 3 and 5 fixed to the stages 7 and 9 are located perpendicular to the capillary 35. This makes it possible to perform wire bonding on the two magnetic sensor chips 3 and 5 by means of the same instrument 33. Thus, it is possible to improve a manufacturing efficiency regarding magnetic sensors.

It is described that the stage inclination step is performed after the preparation step of the lead frame 1 in the present embodiment, which is not a limitation. That is, the stage inclination step can be performed simultaneously with the preparation step of the lead frame 1.

It is described that the adhesion step is performed after the stage inclination step in the present embodiment, which is not a limitation. That is, the stage inclination step can be performed after the adhesion step.

It is described that the bonding device 31 performs only the wiring step; however, it can perform the adhesion step as well. That is, after the surfaces 7a and 9a of the stages 7 and 9 are positioned in parallel to the planar surface 32a of the base 32, the magnetic sensor chips 3 and 5 are adhered onto the surfaces 7a and 9a of the stages 7 and 9.

It is described that the lead frame 1 is pivotally rotated by means of the instrument 33 in the present embodiment, which is not a limitation. Because, it is simply required that the lead frame 1 be moved so as to locate the surfaces 3a and 5a of the magnetic sensor chips 3 and 5 and the surfaces 17a of the leads 17 perpendicular to the capillary 35.

It is described that the magnetic sensor chips 3 and 5 are adhered onto the surfaces 7a and 9a of the stages 7 and 9 via silver pastes in the adhesion step of the present embodiment, which is not a limitation. Because, it is simply required that the magnetic sensor chips 3 and 5 be reliably adhered to the states 7 and 9.

The present embodiment refers to the lead frame 1 having the two stages 7 and 9; but this is not a limitation. That is, the present embodiment can be easily modified and applied to any types of lead frames each having one stage or three or more stages. In other words, the present embodiment is applicable to a manufacturing method for a physical quantity sensor having one physical quantity sensor chip or three or more physical quantity sensor chips by use a bonding device therefor.

It is described that numerous lead frames are formed on a single sheet of the thin metal plate 25 in the present embodiment, which is not a limitation. That is, it is possible to form a single lead frame on a single thin metal plate.

The frame 11 has the rectangular frame portion 15 having a rectangular shape in a plan view in the present embodiment, which is not a limitation. Because, it is simply required that the frame 11 has a frame portion allowing the leads 17 to project inwardly therefrom. For example, the frame portion can be formed in a circular shape in a plan view, or it can be formed to have a three-dimensional structure.

Each of the stages 7 and 9 is formed in a rectangular shape in a plan view in the present embodiment, which is not a limitation. Because, it is simply required that the stages 7 and 9 be shaped to allow the magnetic sensor chips 3 and 5 to be adhered onto the surfaces 7a and 9a thereof. That is, each of the stages 7 and 9 can be formed in a circular shape or an elliptical shape in a plan view; alternatively, each of the stages 7 and 9 can be shaped to have through holes running through in the thickness direction thereof or formed in a mesh-like shape, for example.

The resin mold section 49 integrally fixes the magnetic sensor chips 3 and 5, the leads 17, and the stages 7 and 9 therein in the present embodiment, which is not a limitation. For example, it is possible to use a box-like structure (serving as a package) having an internal space in which the magnetic sensor chips 3 and 5, the leads 17, and the stages 7 and 9 are integrally fixed together.

The bonding device 1 makes it possible that the capillary 35 is located perpendicular to the planar surface 32a of the base 32 in the present embodiment, which is not a limitation. Because, it is simply required that the capillary 35 be located opposite to the planar surface 32a of the base 32. That is, the capillary 35 can be inclined by a prescribed angle with respect to the planar surface 32a of the base 32.

The present embodiment is applied to a magnetic sensor for detecting bearings of geomagnetism in a three-dimensional space; but this is not a limitation. That is, the present embodiment is applicable to any types of physical quantity sensors for detecting directions and bearings in a three-dimensional space. For example, the present embodiment can be applied to an acceleration sensor having acceleration sensor chips for detecting the direction and magnitude of acceleration, for example.

2. Second Embodiment

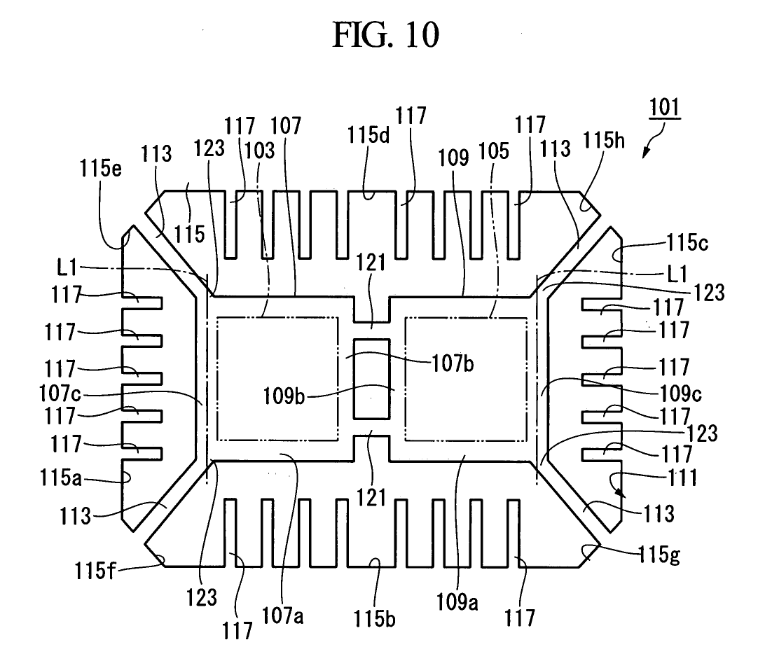

A second embodiment of the present invention will be described with reference to FIGS. 10-14, 15A, 15B, and 16-19. Similar to the first embodiment, the second embodiment refers to a manufacturing method for a magnetic sensor by use of a bonding device.

FIG. 10 shows a lead frame 101 including stages 107 and 109 having rectangular shapes for mounting magnetic sensor chips 103 and 105, a frame 111 for supporting the stages 107 and 109, and interconnection leads 113 for interconnecting the stages 107 and 109 and the frame 111. All the stages 107 and 109, the frame 111, and the interconnection leads 113 are integrally formed together.

The frame 111 includes a rectangular frame portion 115 having a rectangular shape in a plan view surrounding the stages 107 and 109, and numerous leads 117 inwardly projecting from four sides 115a to 115d of the rectangular frame portion 115.

A plurality of the leads 117 are formed with respect to each of the four sides 115a to 115d of the rectangular frame portion 115. They are used to establish electric connections with bonding pads (not shown) of the physical quantity sensor chips 103 and 105.

The magnetic sensor chips 103 and 110 are mounted on surfaces 107a and 109a of the stages 107 and 109 respectively and are arranged along the opposite sides 115b and 115d of the rectangular frame portion 115.

Two stage interconnection portions 121 are formed on terminal ends 107b and 109b of the stages 107 and 109 so as to interconnect the stages 107 and 109 together. The stage interconnection portions 121, which are easy to deform, are used to prevent the stages 107 and 109 from unexpectedly shaking or moving.

The interconnection leads 113 project inwardly from four corners 115e to 115h toward terminal ends 107c and 109c of the stages 107 and 109. Internal ends of the interconnection leads 113 are interconnected to side ends of the terminal ends 107c and 109c of the stages 107 and 109.

Easy-to-deform portions 123 are formed at the internal ends of the interconnection leads 113 positioned in proximity to the terminal ends 107c and 109c of the stages 107 and 109. The easy-to-deform portions 123 are easily deformed so as to rotatably incline the stages 107 and 109 about axial lines L1 perpendicular to the thickness direction of the rectangular frame portion 115.

The easy-to-deform portions 123 are realized by channels recessed in the thickness direction of the lead frame 101 or cutouts formed by partially cutting the interconnection leads 113 in their width direction. The channels or cutouts can be formed simultaneously with the formation of the lead frame 101 on a thin metal plate.

Next, a manufacturing method for a magnetic sensor using the lead frame 101 will be described in detail.

First, the aforementioned lead frame 101 is provided in a preparation step. The lead frame 101 is subjected to press working so that, as shown in FIG. 11, the stages 107 and 109 rotate about the axial lines L1 and are therefore inclined with respect to the rectangular frame portion 115 and the leads 117 in a stage inclination step.

Due to the press working performed in the stage inclination step, the easy-to-deform portions 123 of the interconnection leads 113 and the stage interconnection portions 121 are deformed so that the stages 107 and 109 are rotatably inclined about the axial lines L1. As shown in FIG. 11, in the stage inclination step, the terminal ends 107c and 109c of the stages 107 and 109 are shifted in position with respect to the rectangular frame portion 115 and the leads 117 in the thickness direction of the thin metal plate. In the lead frame 101, the stages 107 and 109 are inclined by prescribed angles with respect to the rectangular frame portion 115 and the leads 117.

After completion of the stage inclination step, the magnetic sensor chips 103 and 105 are adhered onto the surfaces 107a and 109a of the stages 107 and 109 via silver pastes in an adhesion step. Numerous bonding pads 127 and 129 to be electrically connected with the leads 117 are formed on surfaces 103a and 105a of the magnetic sensor chips 103 and 105. The bonding pads 127 and 129 are disposed on the terminal ends 107c and 109c of the stages 107 and 109 along the axial lines L1.

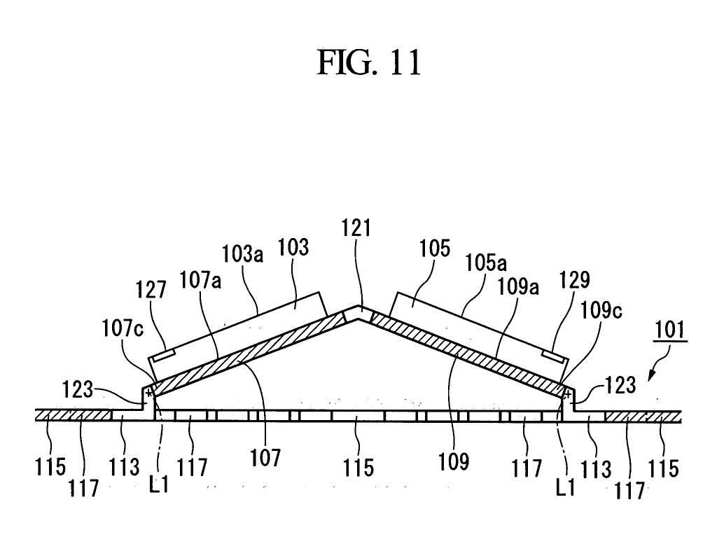

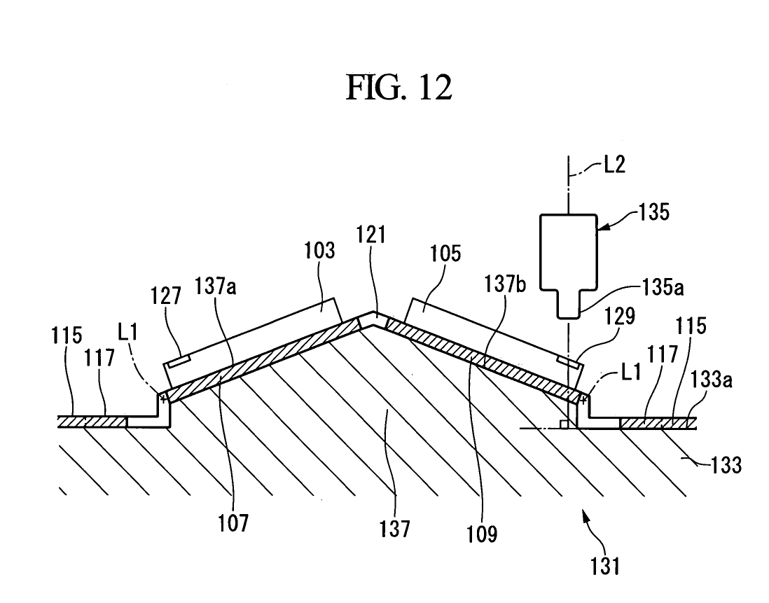

After completion of the adhesion step, as shown in FIG. 12, a bonding device 131 is used to perform a wedge bonding method so as to electrically connect the bonding pads 127 and 129 of the magnetic sensor chips 103 and 105 and the leads 117 together via metal wires (not shown) in a wiring step.

The bonding device 131 includes a base 133 for mounting the lead frame 101 and a wedge tool 135 for arranging wires between the bonding pads 127 and 129 and the leads 117.

The base 133 has a wedge-shaped stage support 137, which projects from a planar surface 133a thereof. The stage support 137 has a pair of slopes 137a and 137b, which are respectively inclined with respect to the planar surface 133a of the base 133. Hence, the stages 107 and 109 are respectively mounted on the slopes 137a and 137b.

When the lead frame 101 is mounted on the base 133, the rectangular frame portion 115 and the leads 117 are mounted on the planar surface 133a, and the stages 107 and 109 are mounted on the slopes 137a and 137b of the stage support 137. Thus, it is possible to hold the stages 107 and 109 in an inclined manner with respect to the rectangular frame portion 115 and the leads 117.

In the wiring step, heat and mechanical stress occur due to wire bonding. Therefore, it is preferable that the base 133 be composed of a prescribed metal having resistance to the heat and mechanical stress.

The wedge tool 135 is arranged in such a way that a center axial line L2 thereof is laid perpendicular to the planar surface 133a of the base 133, in other words, a tip end 135a thereof is positioned opposite to the surfaces 103a and 105a of the magnetic sensor chips 103 and 105 and surfaces 117a of the leads 117 respectively. The wedge tool 135 can move horizontally along the planar surface 133a of the base 133 and can also move vertically in a direction perpendicular to the planar surface 133a of the base 133. In addition, the wedge tool 135 can rotate about the center axial line L2.

As shown in FIG. 13, the tip end 135a of the wedge tool 135 includes a first planar surface 135b, which is perpendicular to the center axial line L2, and a second planar surface 135c, which is slightly inclined with respect to the first planar surface 135b, wherein the first and second planar surfaces 135b and 135c adjacently join together. An inclination angle formed between the first and second planar surfaces 135b and 135c substantially matches each of the inclination angles formed between the surfaces 103a and 105a of the magnetic sensor chips 103 and 105, which are mounted on the stages 107 and 109, and the surfaces 117a of the leads 117.

Guide channels 137a and 137b are respectively recessed in the first and second planar surfaces 135b and 135c and are linearly elongated along the first and second planar surfaces 135b and 135c. The guide channels 137a and 137b are elongated in a coupling direction (i.e., directions H and G) of the first and second planar surfaces 135b and 135c and are mutually connected together. Wires are laid in the guide channels 137a and 137b, which thus allow them to be moved in the coupling directions of the first and second planar surfaces 135b and 135c.

Each of the guide channels 137a and 137b has prescribed dimensions, in which a depth thereof is smaller than the diameter of a wire and the diameter of a through hole 139. When a wire is laid in the guide channels 137a and 137b, it may partially project from the planar surfaces 135b and 135c respectively. The wedge tool 135 has the through hole 139 for introducing a wire from a side portion 135d thereof toward the first planar surface 135b; therefore, the through hole 139 communicates with the end of the guide channel 137a of the first planar surface 135b.

Therefore, a wire inserted into the side portion 135d of the wedge tool 135 moves on the first and second planar surfaces 135b and 135c while being guided via the guide channels 137a and 137b.

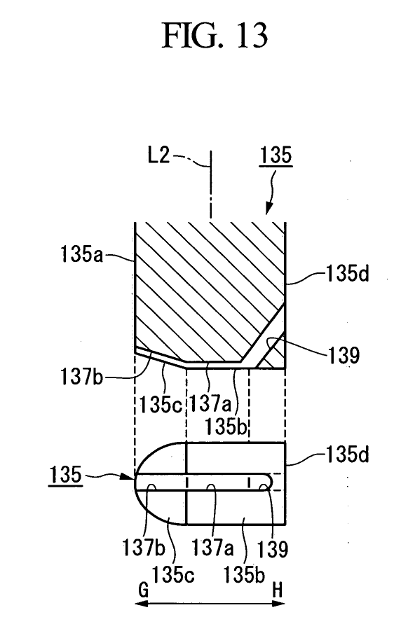

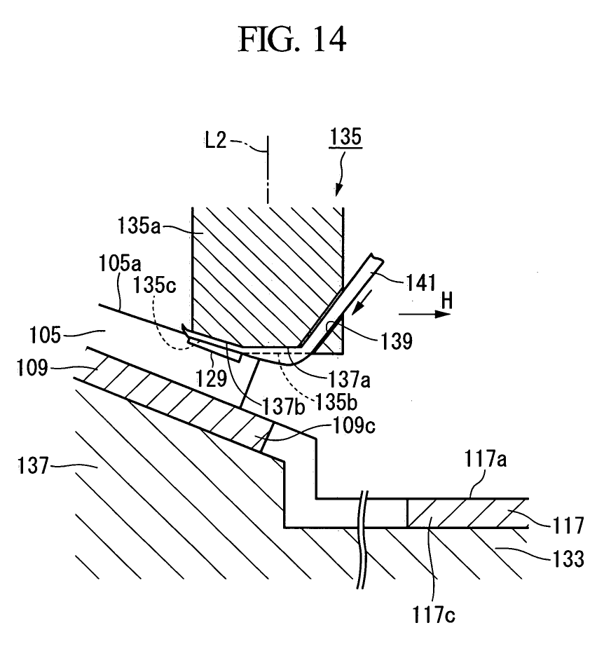

The aforementioned wiring step is performed using the bonding device 131 having the aforementioned constitution. In the wiring step, as shown in FIG. 14, one end of a wire 141 discharged from the wedge tool 135 is firstly bonded onto the bonding pad 129 formed on the surface 105a of the magnetic sensor chip 105 via the through hole 139.

In the above, after the wire 141 is laid in the guide channel 137b of the second planar surface 135c, the wedge tool 135 moves along the center axial line L2 so the one end of the wire 141 is tightly held between the second planar surface 135c of the wedge tool 135 and the bonding pad 129. In this state, the second planar surface 135c is arranged in parallel with the surface 105a of the magnetic sensor chip 105; hence, the wire 141 laid in the guide channel 137b can be entirely and uniformly pressed toward the bonding pad 129 by means of the second planar surface 135c. In this state, heat and ultrasonic vibration are applied to the wire 141 so that one end of the wire 141 reliably joins the bonding pad 129.

After one end of the wire 141 completely joins the bonding pad 129, the wedge tool 135 moves along the longitudinal direction (i.e., a direction H) of the guide channels 137a and 137b to separate from the surface 105a of the magnetic sensor chip 105 while it is continuously discharging the wire 141 therefrom. Therefore, the wire 141 moves in the longitudinal direction of the guide channels 137a and 137b.

The wedge tool 135 moves to a tip end 117c of the lead 117 adjoining the terminal end 109c of the stage 109, so that, as shown in FIG. 15A, the other end of the wire 141 discharged from the wedge tool 135 joins the surface 117a of the lead 117.

In the above, the wedge tool 135 moves along the center axial line L2 while the wire 141 is laid in the guide channel 137a of the first planar surface 135b, so that the other end of the wire 141 is tightly held between the first planar surface 135b and the surface 117a of the lead 117. In this state, the first planar surface 135b is arranged in parallel with the surface 117a of the lead 117; hence, it is possible to uniformly press the wire 141 laid in the guide channel 137a toward the surface 117a of the lead 117 by means of the first planar surface 135b. Then, heat and ultrasonic vibration are applied to the wire 141 so that the other end of the wire 141 joins the surface 117a of the lead 117.

Thereafter, as shown in FIG. 15A, the wedge tool 135 separates from the surface 117a of the lead 117 while it is continuously discharging the wire 141. Lastly, the wedge tool 135 stops supplying the wire 141 from the through hole 139; then, the wedge tool 135 further moves to separate from the surface 117a of the lead 117, so that the wire 14 is broken. Thus, an electric connection is completely established between the bonding pad 129 of the magnetic sensor chip 105 and the lead 117.

After the wires 141 are completely laid between the magnetic sensor chip 105 and the leads 117 respectively, the wedge tool 135 operates to establish electric connections between the bonding pads 127 of the magnetic sensor chip 103 and the leads 117 via the wires 141 as described above. Herein, the wedge tool 135 rotates in advance by 180° about the center axial line L2 so as to position the second planar surface 135c position in parallel with the surface 103a of the magnetic sensor chip 103.

In the aforementioned wiring step, the wedge tool 135 moves horizontally with respect to the base 133 while it is continuously discharging the wire 141 and while the longitudinal direction of the guide channels 137a and 137b is maintained perpendicular to the axial line L1.

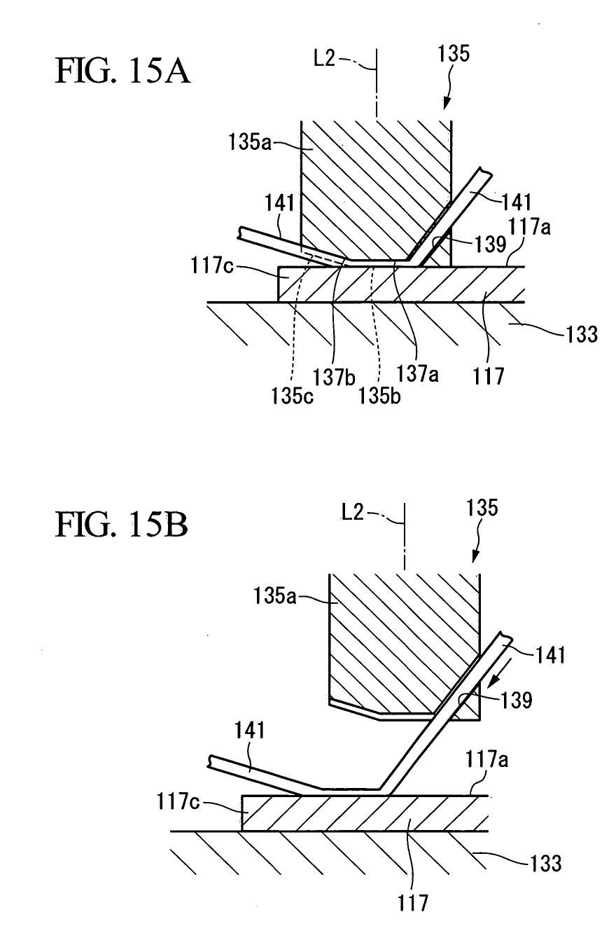

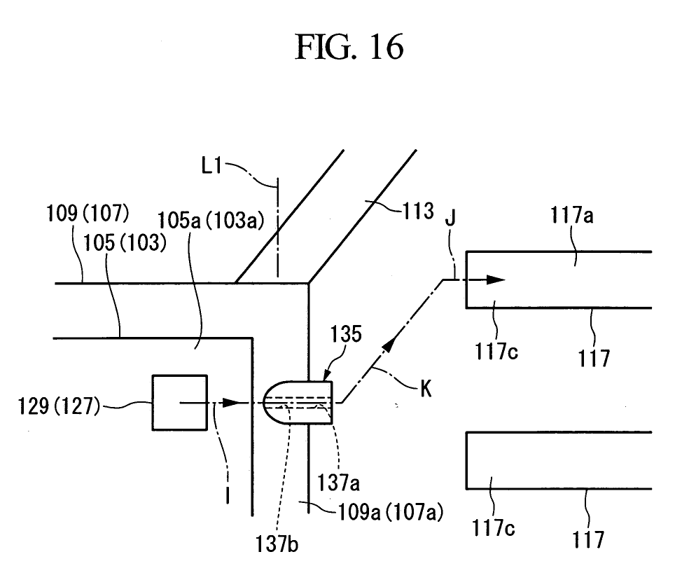

In the above, as shown in FIG. 16, when relative positioning between the bonding pads 127 and 129 and the tip ends 117c of the leads 117 subjected to wire bonding is shifted from the longitudinal direction of the guide channels 137a and 137b, in other words, when positional relationships between the bonding pads 127 and 129 and the tip ends 117c of the leads 117 are not perpendicular to the axial line L1 but are inclined with respect to the axial line L1, the present embodiment inhibits the wedge tool 135 from moving linearly between the bonding pads 127 and 129 and the tip ends 117c of the leads 117. In this case, in order to prevent wires from being subjected to mechanical stress, the wedge tool 135 moves in the longitudinal direction of the guide channels 137a and 137b by way of paths I and J (see FIG. 16) in proximity to the bonding pads 127 and 129 and the leads 117.

Mechanical stress occurs on the wires 141 when the wires 141 being guided in the guide channels 137a and 137b are bent and extended outside of the wedge tool 135 due to differences between the moving direction of the wires 141 in the guide channels 137a and 137b and the moving direction of the wedge tool 135. Since the opposite ends of the wires 141 are respectively bonded onto the bonding pads 127 and 129 and the tip ends 117c of the leads 117, mechanical stress increases remarkably when the moving direction of the wires 141 in the guide channels 137a and 137b further differs from the moving direction of the wedge tool 135 in proximity to the bonding pads 127 and 129 and the tip ends 117c of the leads 117.

The wedge tool 135 moves in a slanted direction by way of a path K, which connects the paths I and J together, in a prescribed range of distance in which it is separated from both the bonding pads 127 and 129 and the surfaces 117a of the leads 117. That is, the wedge tool 135 can be moved in such a slanted direction at a higher position above the bonding pads 127 and 129, the surfaces 103a and 105a of the magnetic sensor chips 103 and 105, and the surfaces 117a of the leads 117. While the wedge tool 135 moves in such a slanted direction by way of the path K, no mechanical stress may occur on the wires 141 even though the moving direction of the wires 141 in the guide channels 137a and 137b differs from the moving direction of the wedge tool 135.

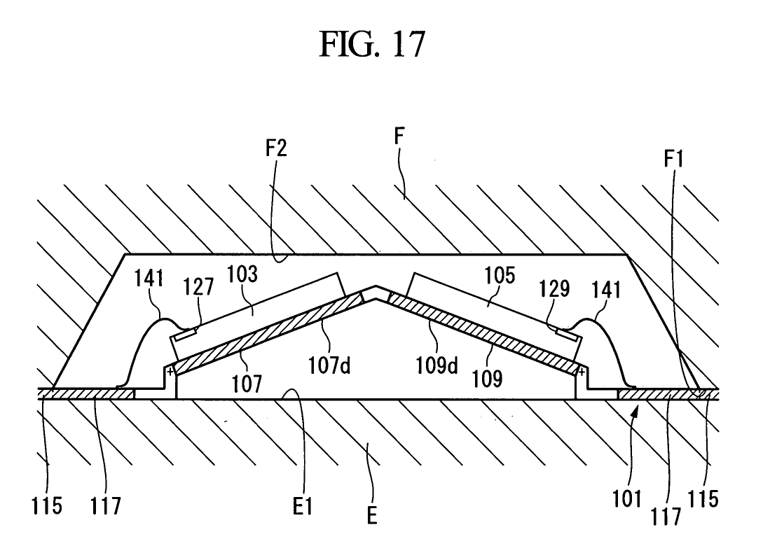

After the completion of the wiring step, the lead frame 101 is extracted from the bonding device 131 and is then set to a pair of metal molds E and F, between which it is vertically held as shown in FIG. 17. Specifically, the rectangular frame portion 115 and the leads 117 are mounted on a planar surface E1 of the lower metal mold E. The upper metal mold F has numerous recesses F2 hollowed from a surface F1 thereof. When the rectangular frame portion 115 of the lead frame 101 is held between the metal molds E and F, the stages 107 and 109 and the leads 117 are completely stored inside of the recess F2.

Then, a melted resin is injected into the space defined by the recess F2 of the upper metal mold F and the planar surface E1 of the lower metal mold E, thus forming a resin mold section 149 for encapsulating the magnetic sensor chips 103 and 105 in a molding step.

Due to the molding step, the stages 107 and 109 are shifted in position in the thickness direction of a thin metal plate with respect to the rectangular frame portion 115. This makes a melted resin easily flow toward backsides 107d and 109d of the stages 107 and 109. As a result, it is possible to fill gaps formed between the backsides 107d and 109d of the stages 107 and 109 and the planar surface E1 of the lower metal mold E with a melted resin.

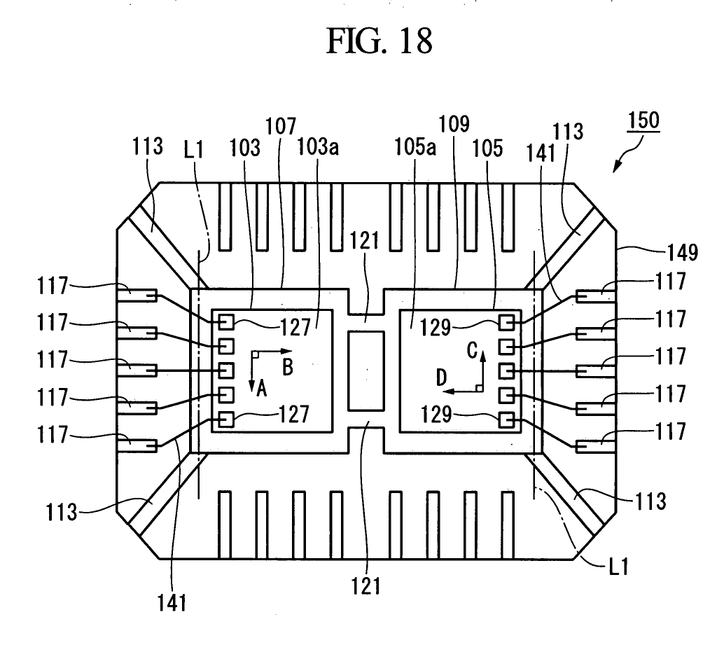

Due to the molding step, the magnetic sensor chips 103 and 105 are mutually inclined with respect to each other and are fixed inside of the resin mold section 149 as shown in FIGS. 18 and 19. Incidentally, it is preferable that the resin be composed of a prescribed material having high fluidity in order not to vary the inclination angles of the magnetic sensor chips 103 and 105 due to a resin flow.

Lastly, the rectangular frame portion 115 is cut so as to individually separate the interconnection leads 113 and the leads 117. Thus, it is possible to completely produce a magnetic sensor 150.

The resin mold section 149 (i.e., a package) of the magnetic sensor 150 has a rectangular shape in a plan view similar to the rectangular frame portion 115. The leads 117 are electrically connected to the magnetic sensor chips 103 and 105 via the metal wires 141. In addition, backsides 117b of the leads 117 are exposed to a lower surface 149a of the resin mold section 149.

Both the magnetic sensor chips 103 and 105 are embedded inside of the resin mold section 149 and are respectively inclined with respect to the lower surface 149a of the resin mold section 149. In addition, terminal ends 103b and 105b of the magnetic sensor chips 103 and 105 positioned opposite to each other are directed toward an upper surface 149c of the resin mold section 149, so that the surfaces 103a and 105a thereof are mutually inclined with respect to each other by an acute angle θ, which is formed between the surface 107a of the stage 107 and the backside 109d of the stage 109.

The magnetic sensor chip 103 is sensitive to magnetic components of an external magnetic field in two directions (i.e., directions A and B), which cross at a right angle with each other along the surface 103a of the magnetic sensor chip 103.

The magnetic sensor chip 105 is sensitive to magnetic components of an external magnetic field in two directions (i.e., directions C and D), which cross at a right angle with each other along the surface 105a of the magnetic sensor chip 105.

Similar to the first embodiment, the directions A and C are reverse to each other and are parallel to the axial lines L1 of the stages 107 and 109 respectively; and the directions B and D are reverse to each other and are perpendicular to the axial lines L1 respectively.

In addition, an A-B plane defined in the directions A and B along the surface 103a of the magnetic sensor chip 103 cross a C-D plane defined in the directions C and D along the surface 105a of the magnetic sensor chip 105 by an acute angle θ (see FIG. 19).

The angle θ formed between the A-B plane and the C-D plane is greater than 0° and less than 90°. Theoretically, when the angle θ is greater than 0°, it is possible to detect bearings of geomagnetism in a three-dimensional space. In order to detect geomagnetic vector components in a direction perpendicular to the A-B plane or the C-D plane with a minimum sensitivity and to calculate them with a small error, it is preferable that the angle θ be greater than 20°. In order to further reduce the error in calculation, it is preferable that the angle θ be greater than 30°.

For example, the aforementioned magnetic sensor 150 is installed in a substrate of a portable information terminal, in which bearings of geomagnetism detected by the magnetic sensor 150 are displayed on a display panel.

According to the manufacturing method for the magnetic sensor 150 using the bonding device 131, when the magnetic sensor chips 103 and 105 are electrically connected to the leads 117 via the wires 141, both ends of the wires 141 are uniformly pressed against the bonding pads 127 and 129 of the magnetic sensor chips 103 and 105 and the surfaces 117a of the leads 117 respectively. Thus, it is possible to improve the joining strengths of the wires 141 joining the bonding pads 127 and 129 and the surfaces 117a of the leads 117.

In contrast to the conventional technology, the present embodiment does not necessarily increase the sizes of the bonding pads 127 and 129 of the magnetic sensor chips 103 and 105 in order to improve joining strengths; hence, it is possible to reduce the sizes of the magnetic sensor chips 103 and 103, thus reducing the overall size of the magnetic sensor 150.

When the opposite ends of the wires 141 respectively join the bonding pads 127 and 129 and the surfaces 117a of the leads 117, the wires 141 can be reliably laid on the planar surfaces 135b and 135c of the wedge tool 135, which thus reliably press the wires 141 against the bonding pads 127 and 129 and the surfaces 117a of the leads 117.

In addition, the wires 141 can be accurately positioned on the planar surfaces 135b and 135c by means of the guide channels 137a and 137b. That is, it is possible to easily establish positioning of the wires 141 with respect to the bonding pads 127 and 129 and the surfaces 117a of the leads 117.

When the wedge tool 135 moves between the magnetic sensor chips 103 and 105 and the leads 117, the moving direction of the wedge tool 135 is forced to match the longitudinal direction of the guide channels 137a and 137b. Therefore, even when the wires 141 move in the longitudinal direction of the guide channels 137a and 137b, it is possible to reliably avoid the occurrence of mechanical stress on the wires 141. That is, it is possible to prevent the wires 141 from being damaged.

The present embodiment is described such that one ends of the wires 141 join the bonding pads 127 and 129, and then the other ends of the wires 141 join the surfaces 117a of the leads 117. Instead, one ends of he wires 141 join the surfaces 117a of the leads 117, and then the other ends of the wires 141 join the bonding pads 127 and 129. Specifically, one ends of the wires 141 join the surfaces 117a of the leads 117 by means of the first planar surface 135b of the wedge tool 135, and then the other ends of the wires 141 join the bonding pads 127 and 129 by means of the second planar surface 135c of the wedge tool 135.

It is described that the guide channels 137a and 137b are respectively formed in the planar surfaces 135b and 135c in the present embodiment, which is not necessarily a limitation. It is simply required that the wedge tool 135 has the first planar surface 135b, which can be arranged in parallel with the surfaces 117a of the leads 117, and the second planar surface 135c, which can be arranged in parallel with the surfaces 103a and 105a of the magnetic sensor chips 103 and 105 inclined with respect to each other.

The stage inclination step is not necessarily performed after the preparation step of the lead frame 101. That is, it is possible to simultaneously perform the stage inclination step and the preparation step.

The adhesion step is not necessarily performed after the stage inclination step. That is, it is possible to simultaneously perform the stage inclination step after the adhesion step.

In the adhesion step, the magnetic sensor chips 103 and 105 are not necessarily adhered onto the surfaces 107a and 109a of the stages 107 and 109 via silver pastes. That is, it is simply required that the magnetic sensor chips 103 and 105 be adhered to the stages 107 and 109.

The present embodiment refers to the lead frame 101 having the two stages 107 and 109, but this is not a limitation. That is, the present embodiment can be applied to any types of lead frames each having one or three or more stages. That is, the present embodiment is applicable to manufacturing methods for magnetic sensor chips, each having one or three or more magnetic sensor chips, by use of bonding devices.

The frame 111 is not necessarily equipped with the rectangular frame portion 115 having a rectangular shape in a plan view. That is, it is simply required that the frame 111 has a certain frame portion allowing the leads 117 to project inwardly. The frame portion can be formed in a circular shape in a plan view; alternatively, it can be formed to have a three-dimensional structure.

Each of the stages 107 and 109 is not necessarily formed in a rectangular shape in a plan view. That is, it is required that the stages 107 and 109 be shaped to allow the magnetic sensor chips 103 and 105 to be adhered onto the surfaces 107a and 109a. For example, each of the stages 107 and 109 can be formed in a circular shape or an elliptical shape in a plan view; alternatively, each of them can be formed to have through holes running through the thickness direction thereof or formed in a mesh-like shape.

The magnetic sensor chips 103 and 105, the leads 117, and the stages 107 and 109 are not necessarily integrally fixed inside of the resin mold section 149. For example, it is possible to integrally fix the magnetic sensor chips 103 and 105, the leads 117, and the stages 107 and 109 in an internal space of a box-like package.

The present embodiment is applied to a magnetic sensor for detecting directivity of magnetism in a three-dimensional space, but this is not a limitation. That is, the present embodiment is applicable to any types of physical quantity sensors for detecting bearings and directions in a three-dimensional space. For example, the present embodiment can be applied to acceleration sensors having acceleration sensor chips for detecting magnitude and directivity of acceleration instead of magnetic sensor chips.

3. Variations

The aforementioned first and second embodiments can be partially modified and varied in a variety of ways; hence, preferred variations will be described below.

(1) First Variation

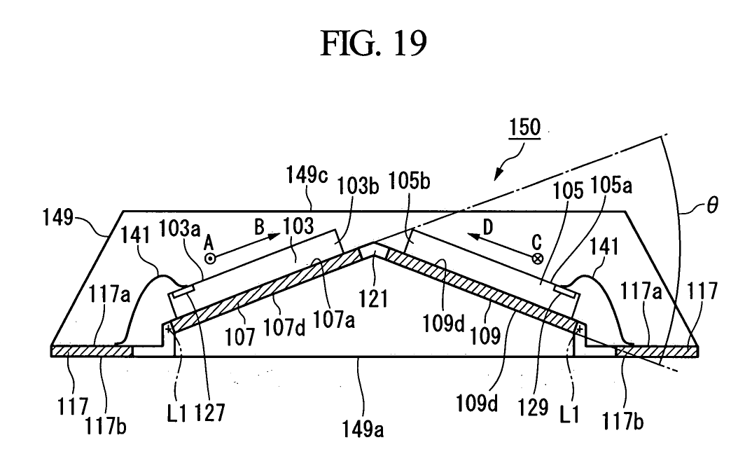

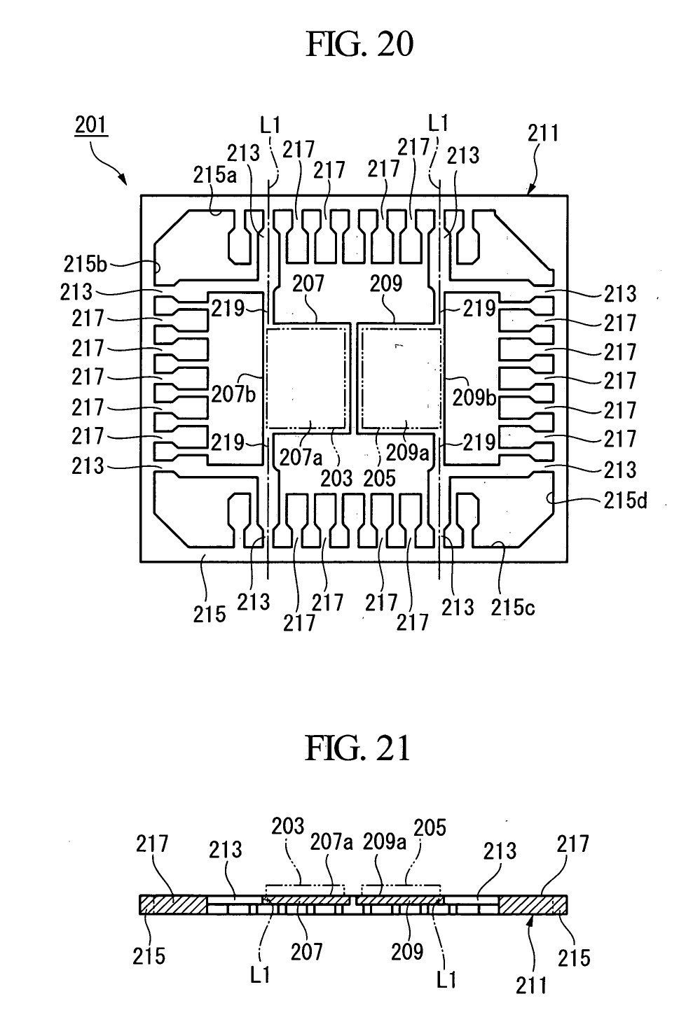

The aforementioned lead frames 1 and 101 used in the first and second embodiments shown in FIGS. 1 and 10 can be partially modified to include shape memory alloys (e.g., Ti—Ni alloys) allowing physical quantity sensor chips to be respectively inclined. Details of a first variation will be described with reference to FIGS. 20 to 27.

As shown in FIGS. 20 and 21, a lead frame 201 includes two stages 207 and 209 having rectangular shapes for mounting magnetic sensor chips 203 and 205, a frame 211 for supporting the stages 207 and 209, and interconnection leads 213 for interconnecting the stages 207 and 209 and the frame 211. All the stages 207 and 209, the frame 211, and the interconnection leads 213 are integrally formed together.

The frame 211 includes a rectangular frame portion 215 having a rectangular shape in a plan view for surrounding the stages 207 and 209 and numerous leads 217 projecting inwardly from four sides 215a to 215d of the rectangular frame portion 215.

A plurality of leads 217 are formed with respect to each of the four sides 215a to 215d of the rectangular frame portion 215 and are electrically connected to bonding pads (not shown) of the magnetic sensor chips 203 and 205.

The stages 207 and 209 are each formed in a rectangular shape in a plan view so as to mount the magnetic sensor chips 203 and 205 thereon. They are arranged along the sides 215b and 215d of the rectangular frame portion 215 respectively.

The interconnection leads 213 project inwardly toward terminal ends 207b and 209b of the stages 207 and 209 from the four sides 215a to 215d of the rectangular frame portion 215 respectively. Internal ends of the interconnection leads 213 are interconnected to side ends of the terminal ends 207b and 209b of the stages 207 and 209.

Twisting portions 219 are formed at the internal ends of the interconnection leads 213. The twisting portions 219 are easy to be deformed so that the stages 207 and 209 are rotatably inclined with respect to the frame 211 about axial lines L1 drawn perpendicular to the thickness direction of the rectangular frame portion 215.

The twisting portions 219 are formed using channels, which are recessed in the thickness direction of the lead frame 201 by way of photo-etching, or using cutouts, which are formed by partially cutting the interconnection leads 213; hence, they are easy to be deformed. The aforementioned channels or cutouts can be formed simultaneously with the formation of the lead frame 201 using a thin metal plate.

Next, a manufacturing method for a magnetic sensor using the aforementioned lead frame 201 will be described.

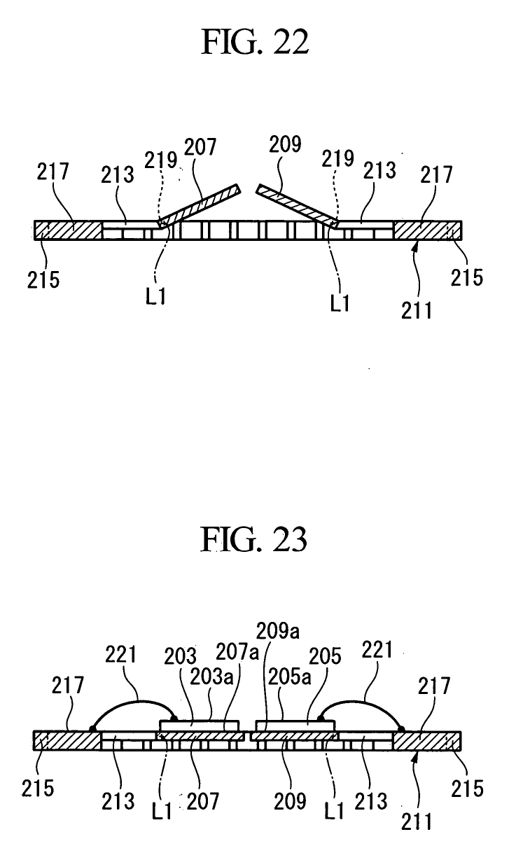

First, there is provided a thin metal plate having numerous lead frames 201 in a preparation step. The lead frame 201 is heated at a restoration temperature of a Ti—Ni alloy (i.e., 300° C.) or more and is then subjected to press working, so that, as shown in FIG. 22, the stages 207 and 209 are respectively inclined about the axial lines L1 by prescribed inclination angles with respect to the frame 211 in a stage inclination step. In the stage inclination step, the twisting portions 219 of the interconnection leads 213 are deformed so that the stages 207 and 209 rotate about the axial lines L1 and are thus inclined by the prescribed inclination angles with respect to the frame 211.

The lead frame 201 is cooled down at a prescribed temperature, which is lower than the restoration temperature (i.e., 300° C.) of the Ti—Ni alloy and is then subjected to press working, whereby the twisting portions 219 are subjected to plastic deformation, so that, as shown in FIG. 23, the stages 207 and 209 are forced to be planar with respect to the frame 211 in a planation step. After the planation step, the magnetic sensor chips 203 and 205 are respectively adhered onto surfaces 207a and 209a of the stages 207 and 209 via silver pastes in an adhesion step. In the adhesion step, the lead frame 201 is heated at a prescribed temperature ranging from 150° C. to 200° C. in order to heat the silver pastes.

Thereafter, wire bonding is performed so as to provide wires 221 between bonding pads, which are formed on surfaces 203a and 205a of the magnetic sensor chips 203 and 205, and the leads 217, which are thus electrically connected together in a wiring step. In the wiring step, the lead frame 201 is heated at a prescribed temperature ranging from 230° C. to 250° C.

Since the heating temperatures adapted to the adhesion step and wiring step are lower than the restoration temperature (i.e., 300° C.) of the Ti—Ni alloy, the twisting portions 219 are not deformed in these steps.

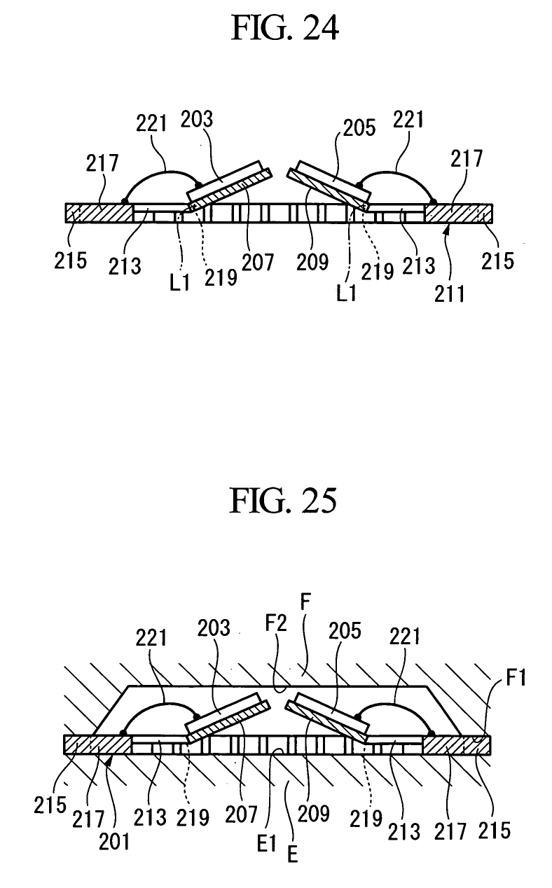

After the wiring step, the lead frame 201 is heated at the restoration temperature (i.e., 300° C.) of the Ti—Ni alloy, whereby, as shown in FIG. 24, the twisting portions 219 are deformed so that the stages 207 and 209 are inclined again by the prescribed inclination angles with respect to the frame 211 in a re-inclination step. In the re-inclination step, the lead frame 201 is heated at 300° C. for five seconds.

Thereafter, the lead frame 201 is vertically held between a pair of metal molds E and F as shown in FIG. 25. Specifically, the lower metal mold E has a planar surface E1, on which the rectangular frame portion 215 and the leads 217 are mounted; and the upper metal mold F has a recess F2 hollowed from a surface F1. When the rectangular frame portion 215 is vertically held between the planar surface E1 of the lower metal mold E and the surface F1 of the upper metal mold F, the magnetic sensor chips 203 and 205 and the stages 207 and 209, which are inclined with respect to each other, are completely stored inside of the recess F2.

Then, a melted resin is injected into a space defined by the planar surface E1 of the lower metal mold E and the recess F2 of the upper metal mold F, so that all the magnetic sensor chips 203 and 205, the stages 207 and 209, the interconnection leads 213, and the leads 217 are embedded and integrally fixed inside of a resin mold section in a molding step. In the molding step, a melted resin heated at a prescribed temperature of 175° C. is injected into the space within one minute; then, it is subjected to curing for four hours while maintaining the prescribed temperature of 175° C. In the molding step, the heated temperature of a resin is lower than the restoration temperature of 300° C. of the Ti—Ni alloy, thus preventing the twisting portions 219 from being unexpectedly deformed.

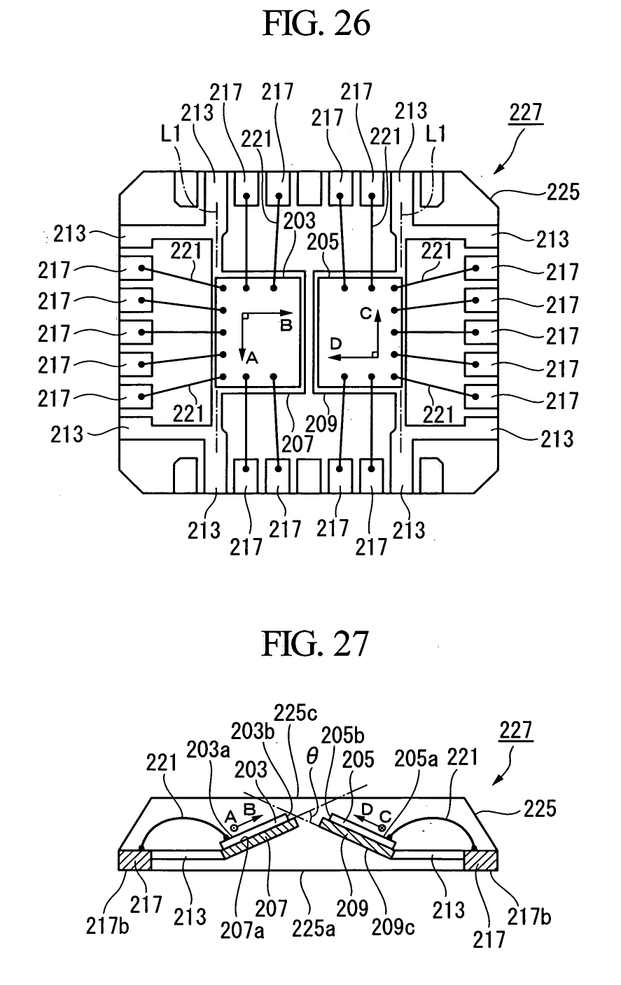

Due to the aforementioned molding step, it is possible to fix the magnetic sensor chips 203 and 205, which are respectively inclined by prescribed angles with respect to the rectangular frame portion 215, inside of a resin mold section 225 as shown in FIGS. 26 and 27. Incidentally, it is preferable that the aforementioned resin be composed of a prescribed material having high fluidity in order not to vary the inclination angles of the magnetic sensor chips 203 and 205 due to a resin flow.

Lastly, the rectangular frame portion 215 is subjected to cutting so as to individually separate the interconnection leads 213 and the leads 217. Thus, it is possible to completely produce a magnetic sensor 227 shown in FIGS. 26 and 27.

The resin mold section 225 of the magnetic sensor 227 has a rectangular shape in a plan view similarly to the rectangular frame portion 215. The leads 217 are electrically connected to the magnetic sensor chips 203 and 205 via the metal wires 221. In addition, backsides 217b of the leads 217 are exposed to a lower surface 225a of the resin mold section 225.

The magnetic sensor chips 203 and 205 are embedded inside of the resin mold section 225 and are respectively inclined with respect to a lower surface 225a of the resin mold section 225. Specifically, terminal ends 203b and 205b of the magnetic sensor chips 203 and 205, which are positioned opposite to each other, are directed toward an upper surface 225c of the resin mold section 225, and the surfaces 203a and 205a are mutually inclined with respect to each other by an acute angle θ, which is formed between the surface 207a of the stage 207 and a backside 209c of the stage 209.

The magnetic sensor chip 203 is sensitive to two components of magnetism lying in two directions of an external magnetic field, i.e., directions A and B, which cross at a right angle with each other along the surface 203a thereof.

The magnetic sensor chip 205 is sensitive to two components of magnetism lying in two directions of an external magnetic field, i.e., directions C and D, which cross at a right angle with each other along the surface 205a thereof.

In the above, the directions A and C are reverse to each other and are parallel with the axial lines L1 for the stages 207 and 209 respectively. The directions B and D are reverse to each other and are perpendicular to the axial lines L1 respectively.

In addition, an A-B plane defined by the directions A and B along the surface 203a of the magnetic sensor chip 203 crosses a C-D plane defined by the directions C and D along the surface 205a of the magnetic sensor chip 205 with an acute angle θ therebetween.

The angle θ formed between the A-B plane and the C-D plane is greater than 0° and is less than 90°. Theoretically, it is possible to detect bearings of geomagnetism in a three-dimensional space when the angle θ is greater than 0°. In order to detect geomagnetic vector components in a vertical direction, perpendicular to the A-B plane or the C-D plane, and to calculate geomagnetic vectors with a small error, it is preferable that the angle θ be greater than 20°. In order to further reduce error in calculation, it is preferable that the angle θ be greater than 30°.

The aforementioned magnetic sensor 227 is installed in a substrate of a portable terminal device (not shown), which in turn displays bearings of geomagnetism on a display panel, for example.

The aforementioned manufacturing method for the magnetic sensor 227 using the lead frame 201 includes the re-inclination step for heating the lead frame 201 at the restoration temperature of the Ti—Ni alloy before the molding step and after the adhesion step and wiring step; hence, it is possible to reliably maintain the inclination angles established by the stage inclination step with respect to the magnetic sensor chips 203 and 205 mounted on the stages 207 and 209. For this reason, it is possible to improve an accuracy regarding the inclination angles set to the magnetic sensor chips 203 and 205 even when an external force is exerted on the stages 207 and 209 whose inclination angles are thus varied with respect to the frame 211 during the transportation of the lead frame 201 after the adhesion step and wiring step and before the molding step. Thus, it is possible to provide the magnetic sensor 227 that is capable of detecting bearings in a three-dimensional space with a high precision.

After the inclination angles are set to the stages 207 and 209 in the stage inclination step, the stages 207 and 209 can be rearranged to be planar with respect to the frame 211. This makes it possible to easily arrange the magnetic sensor chips 203 and 205 on the stages 207 and 209 and to electrically connect the magnetic sensor chips 203 and 205 to the leads 217 with ease.

The re-inclination step is not necessarily performed before the lead frame 201 is vertically held between the metal molds E and F. For example, the re-inclination step can be performed simultaneously when the lead frame 201 is vertically held between the metal molds E and F. In other words, the re-inclination step allows the lead frame 201 vertically held between the metal molds E and F to be heated up to the restoration temperature of the Ti—Ni alloy.

The lead frame 201 is not necessarily composed of a Ti—Ni alloy. It is simply required that the lead frame 201 be composed of a shape memory alloy. Herein, when the restoration temperature of the shape memory alloy is lower than the heating temperature of the lead frame 201 in the adhesion step and wiring step, it is preferable that the stages 207 and 209 be depressed using pins so as not to be unexpectedly inclined in the adhesion step and wiring step.

In addition, the lead frame 201 is not entirely composed of a shape memory alloy. It is simply required that the twisting portions 219, which allow the stages 207 and 209 to be inclined with respect to the frame 211, be each composed of a shape memory alloy.

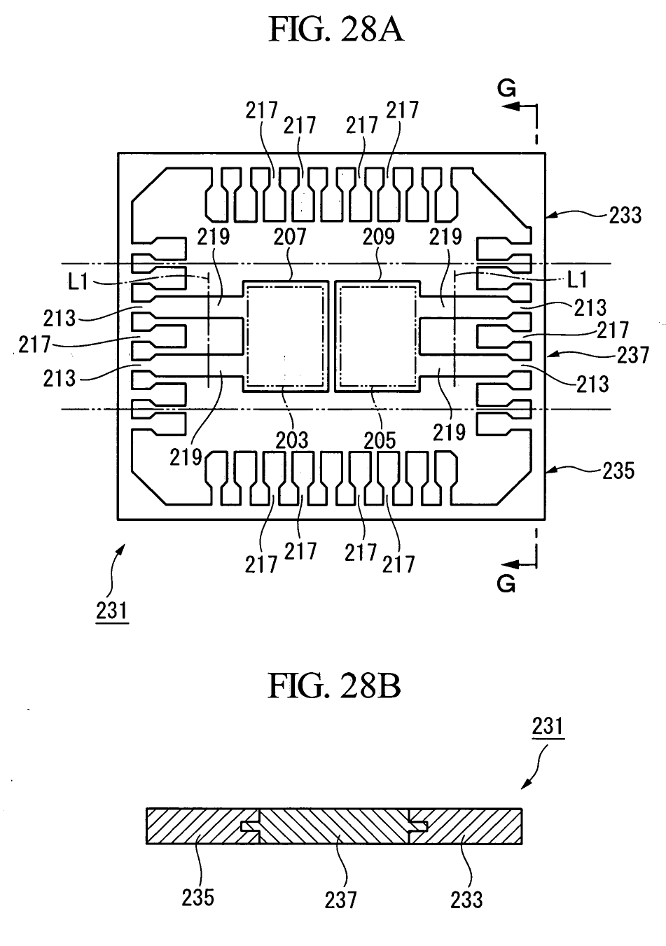

It is possible to modify the aforementioned lead frame 201 for use in manufacturing of a magnetic sensor as shown in FIGS. 28A and 28B, wherein parts identical to those shown in FIG. 20 are designated by the same reference numerals. That is, FIG. 28A shows a lead frame 231 that is formed using a thin metal plate constituted by three types of plates having stripe shapes, in which a plate 237 composed of a shape memory alloy is integrally formed together with plates 233 and 235 each composed of another metal such as copper. Herein, the thin metal plate is subjected to press working and punching so as to form the lead frame 231 in which all the twisting portions 219 are formed in the plate 237 composed of the shape memory alloy.

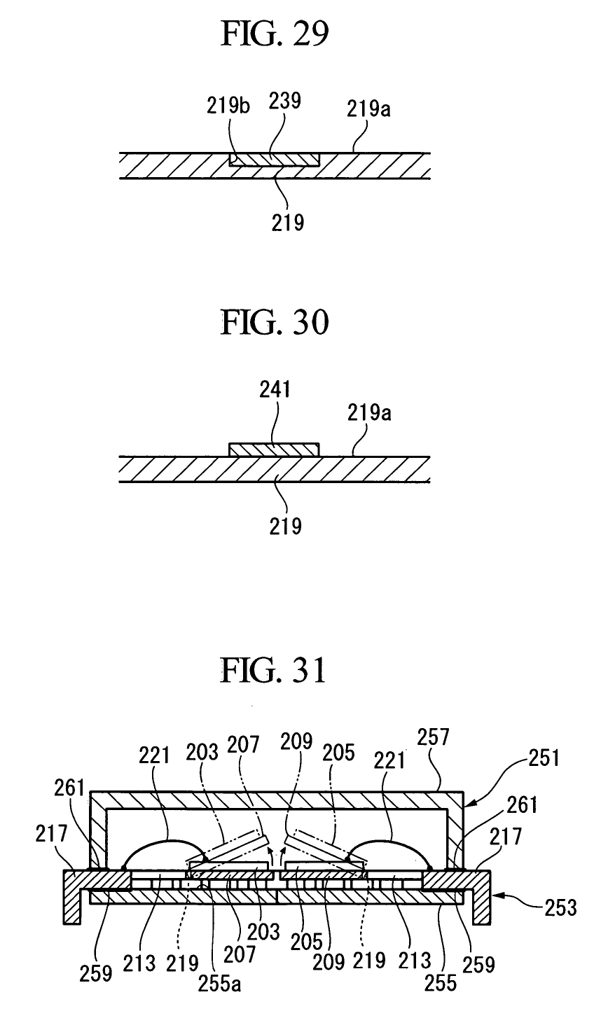

The aforementioned lead frame 231 can be further modified such that only the twisting portions 219 are each formed using a shape memory alloy. Specifically, as shown in FIG. 29, a shape memory alloy member 239 can be arranged inside of a recess 219b hollowed from a surface 219a of a twisting portion 219. In this case, when a lead frame is formed using a thin metal plate composed of copper and the like, the recess 219b is formed on the twisting portion 219 by way of press working or etching; then, the shape memory alloy member 239 is arranged inside of the recess 219b. Alternatively, as shown in FIG. 30, a shape memory alloy member 241 can be adhered onto the surface 219a of the twisting portion 219.

The aforementioned modification is advantageous in that the lead frame can be produced with a relatively low cost because the lead frame is not entirely formed using the shape memory alloy.

All the magnetic sensor chips 203 and 205, the stages 207 and 209, and the leads 217 are not necessarily integrally fixed inside of the resin mold section 225. Instead, as shown in FIG. 31, they can be completely stored inside of a box-like housing 251 (i.e., a ceramic package). The box-like housing 251 is constituted of a base member 255 having a plate-like shape for mounting a lead frame 253 and a cover 257 for covering the lead frame 253 mounted on the base member 255.

In the above, the lead frame 253 is adhered onto a surface 255a of the base member 255 via low-melting-point glass 259 in advance. In this case, the aforementioned stage inclination step can be performed simultaneously with the adhesion. In other words, when the temperature of heat for melting the low-melting-point glass 259 used for the adhesion of the lead frame 253 onto the base member 255 is higher than the restoration temperature of the shape memory alloy, the stages 207 and 209 can be subjected to inclination using the heat.

In addition, the aforementioned planation step, adhesion step, and wiring step are performed; thereafter, the cover 257 is adhered onto the leads 217 in the periphery of the surface 255a of the base member 255 via low-melting-point glass 261. In this case, the aforementioned re-inclination step can be performed simultaneously with the adhesion. That is, the stages 207 and 209 for mounting the magnetic sensor chips 203 and 205 can be subjected to re-inclination using heat for melting the low-melting-point glass 261.

The aforementioned procedures allow the stage inclination step and re-inclination step to be performed simultaneously with a step for installing the lead frame 253 into the box-like housing 251 and a step for completely storing the lead frame 253 inside of the box-like housing 251. This improves the efficiency for manufacturing a magnetic sensor.

The magnetic sensors 203 and 205 are not necessarily adhered onto the surfaces 207a and 209a of the stages 207 and 209 via silver pastes. It is simply required that the magnetic sensor chips 203 and 205 be reliably adhered onto the stages 207 and 209.

Each of the aforementioned lead frames 201, 231, and 253 does not necessarily include two stages 207 and 209. That is, it is possible to realize lead frames each having one or three or more stages.

The frame 211 does not necessarily have the rectangular frame portion 215 having a rectangular shape in a plan view. It is simply required that the frame 211 has a frame portion allowing the leads 217 to project inwardly therefrom. That is, the frame portion can be formed in a circular shape in a plan view; alternatively, it can be formed to have a three-dimensional structure.

Each of the stages 207 and 209 is not necessarily formed in a rectangular shape in a plan view. It is simply required that the stages 207 and 209 be formed to allow the magnetic sensor chips 203 and 205 to be adhered onto the surfaces 207a and 209a thereof. That is, each of the stages 207 and 209 can be formed in a circular shape or an elliptical shape in a plan view. Alternatively, each of them has through holes running through the thickness direction thereof, or it is formed in a mesh-like shape.

(2) Second Variation

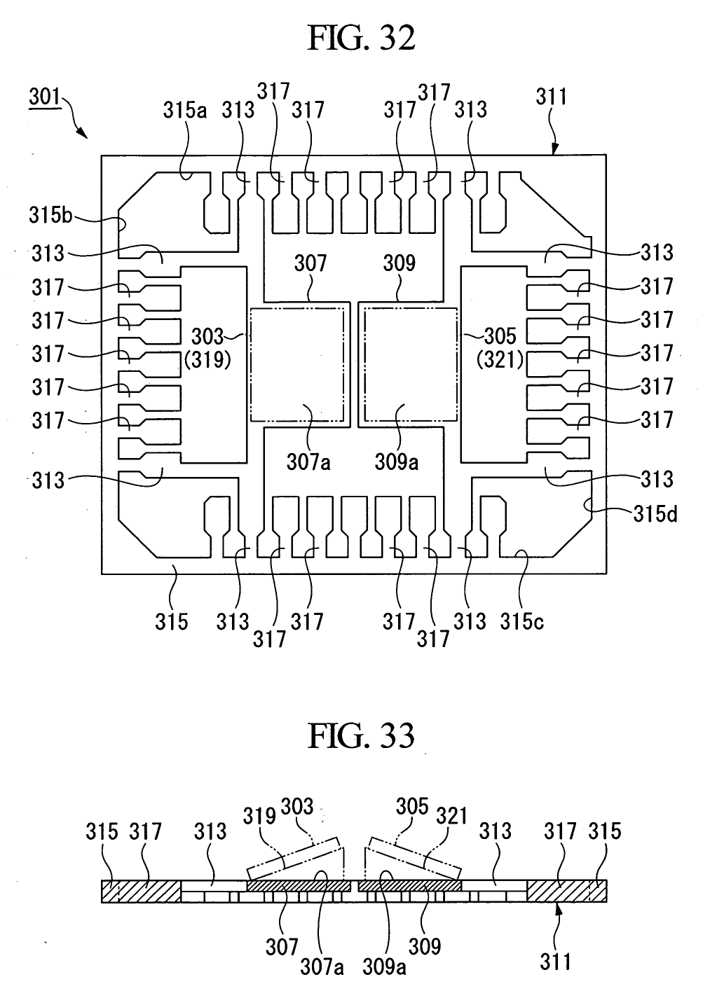

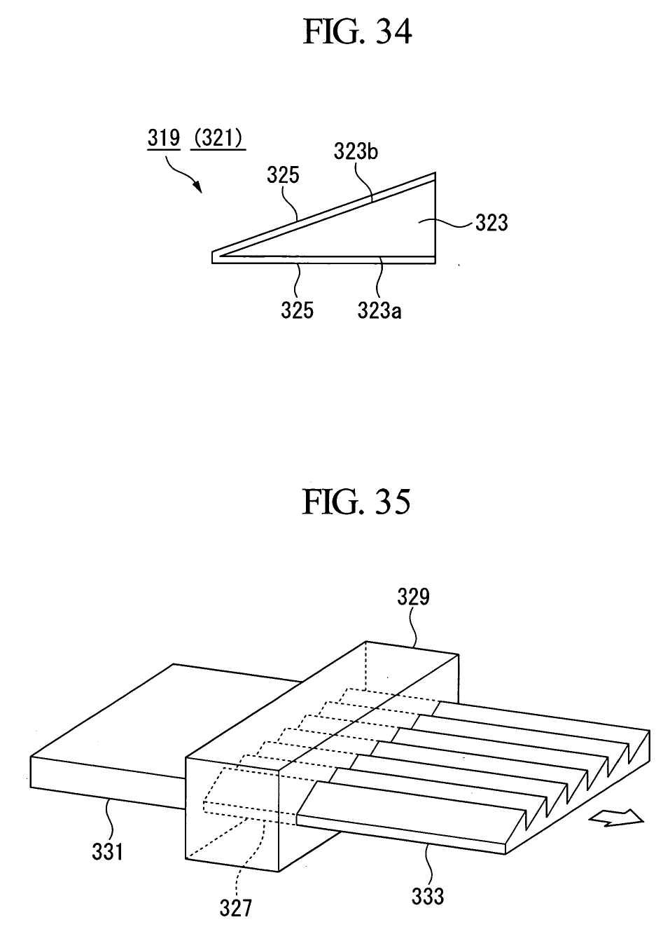

The aforementioned first and second embodiments can be partially modified such that each of the physical quantity sensor chips be inclined by means of an inclination member having a wedge shape with respect to each of the stages formed in the lead frame. Details of a second variation will be described with reference to FIGS. 32 to 42.

As shown in FIGS. 32 and 33, a lead frame 301 includes two stages 307 and 309 having rectangular shapes, a frame 311 for supporting the stages 307 and 309, and a plurality of interconnection leads 313 for interconnecting the stages 307 and 309 and the frame 311 together. All the stages 307 and 309, the frame 311, and the interconnection leads 313 are integrally formed together.

The frame 311 includes a rectangular frame portion 315 having a rectangular shape in a plan view for surrounding the stages 307 and 309, and numerous leads 317 projecting inwardly from four sides 315a to 315d of the rectangular frame portion 315. A plurality of leads 317 are formed with respect to each of the four sides 315a to 315d of the rectangular frame portion 315. They are electrically connected to bonding pads (not shown) of magnetic sensor chips 303 and 305.

The magnetic sensor chips 303 and 305 are mounted on surfaces 307a and 309a of the stages 307 and 309 via inclination members 319 and 321 having wedge shapes. The stages 307 and 309 are respectively arranged along the longitudinal directions of the sides 315b and 315d of the rectangular frame portion 315.

The interconnection leads 313 project inwardly from the sides 315a to 315d of the rectangular frame portion 315 toward the stages 307 and 309. Internal ends of the interconnection leads 313 are connected to side ends of the stages 307 and 309.

Next, a manufacturing method for a magnetic sensor using the lead frame 301 will be described in detail.

First, there is provided the lead frame 301 in a preparation step. The magnetic sensor chips 303 and 305 are respectively adhered onto the surfaces 307a and 309a of the stages 307 and 309 via the inclination members 319 and 321 having wedge shapes in an adhesion step.

Each of the inclination members 319 and 321 used in the adhesion step is constituted by a wedge base member 323 having a bottom 323a and a slope 323b, which is inclined by an acute angle with respect to the wedge base member 323, as well as an adhesive thin film (or an adhesive layer) 325, which is formed to cover the bottom 323a and the slope 323b. The wedge base member 323 is composed of a resin having insulation and thermoplastic property such as polyimide. The adhesive thin film 325 is composed of a resin having insulation and thermosetting property such as a die-bonding film of polyimide. It is preferable that the wedge base member 323 be composed of a resin, which is not melted at a prescribed temperature at which the adhesive thin film 325 is heated and hardened.

The wedge base member 323 can be formed by way of extrusion molding, for example. For example, as shown in FIG. 35, the wedge base member 323 is formed using a metal mold 329 having a cavity 327 (having a saw-toothed shape), which runs through in an extrusion direction, and a thermoplastic resin 331 as a material of the wedge base member 323. The thermoplastic resin 331 is melted and supplied to the cavity 327 of the metal mold 329, from which a molded member 333 having a saw-toothed shape matching the cavity 327 is extruded from the cavity 327. Lastly, the molded member 333 is divided into pieces, thus producing the wedge base member 323 for use in the inclination members 319 and 321. After the molded member 333 is divided into pieces, the adhesive thin film 325 is adhered to the wedge base member 323 to cover the bottom 323a and slope 323b.

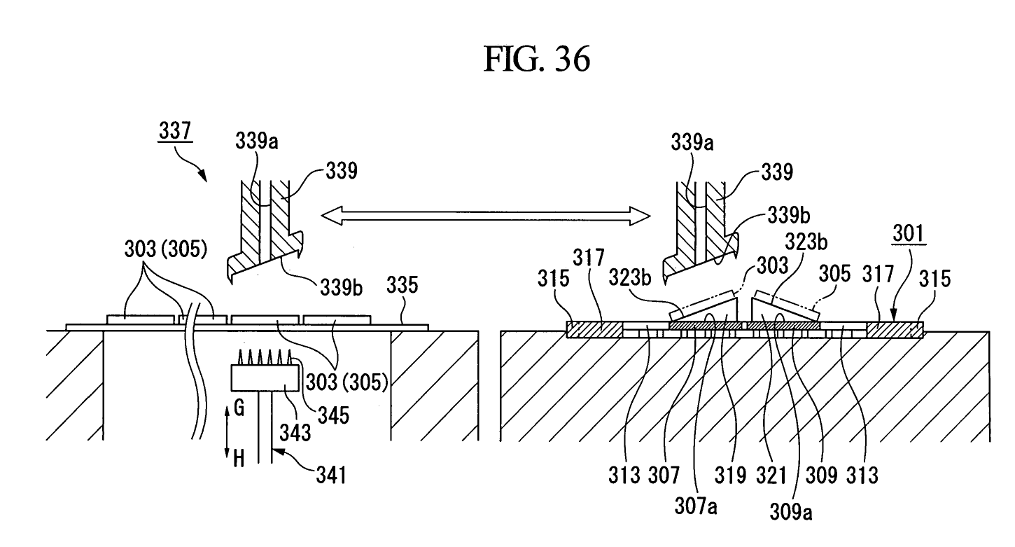

In the adhesion step, as shown in FIG. 36, the inclination members 319 and 321 are mounted on the surfaces 307a and 309a of the stages 307 and 309 respectively in an inclination member mounting step; and then, the magnetic sensor chips 303 and 305 are respectively mounted on the slopes 323b of the inclination members 319 and 321 in a chip mounting step.

In the chip mounting step, the magnetic sensor chips 303 and 305, which are completed in dicing and are adhered on a dicing tape 335, are transported toward the slopes 323b of the inclination members 319 and 321 by means of a transportation device 337 in a transportation step.

The transportation device 337 has a collet 339 for lifting up and holding the magnetic sensor chips 303 and 305 and a pushing unit 341, which is arranged blow the dicing tape 335. The collet 339 has a suction surface 339b for sucking and holding the magnetic sensor chips 303 and 305 by sucking air via a suction hole 339a. The suction surface 339b is inclined with respect to the surfaces 307a and 309a of the stages 307 and 309 and the dicing tape 335 and are parallel with the slope 323b having a prescribed inclination angle. The collet 339 can be moved from above the dicing tape 335 to the slopes 323b of the inclination members 319 and 321.

The pushing unit 341 ascends up and descends down in normal directions (i.e., directions G and H) below the dicing tape 335. The pushing unit 341 has a plurality of needles 345 projecting vertically from a base 343 thereof. The needles 345 can each be extended and contracted from the base 343.

In the transportation step, the collet 339 is firstly arranged above the selected magnetic sensor chip 303 (or 305) adhered on the dicing tape 335; and the pushing unit 341 is arranged below the selected magnetic sensor chip 303 (or 305). Then, the pushing unit 341 ascends up in the direction G so that, as shown in FIG. 37, the needles 345 move upward while partially breaking the dicing tape 335, whereby it pushes up the magnetic sensor chip 303 (or 305) to be peeled off and separated from the dicing tape 335.

Then, the tip ends of the needles 345 are respectively extended or contracted so as to support the magnetic sensor chip 303 (or 305) to be parallel with the suction surface 339b of the collet 339. In this state, the pushing unit 341 further ascends up in the direction G, so that the magnetic sensor chip 303 (or 305) is brought into contact with the suction surface 339b. At this time, air suction is performed via the suction hole 339a, so that the magnetic sensor chip 303 (or 305) is completely sucked and attached to the suction surface 339b of the collet 339 while it is held substantially parallel with the slope 323b of the inclination member 319 (or 321).

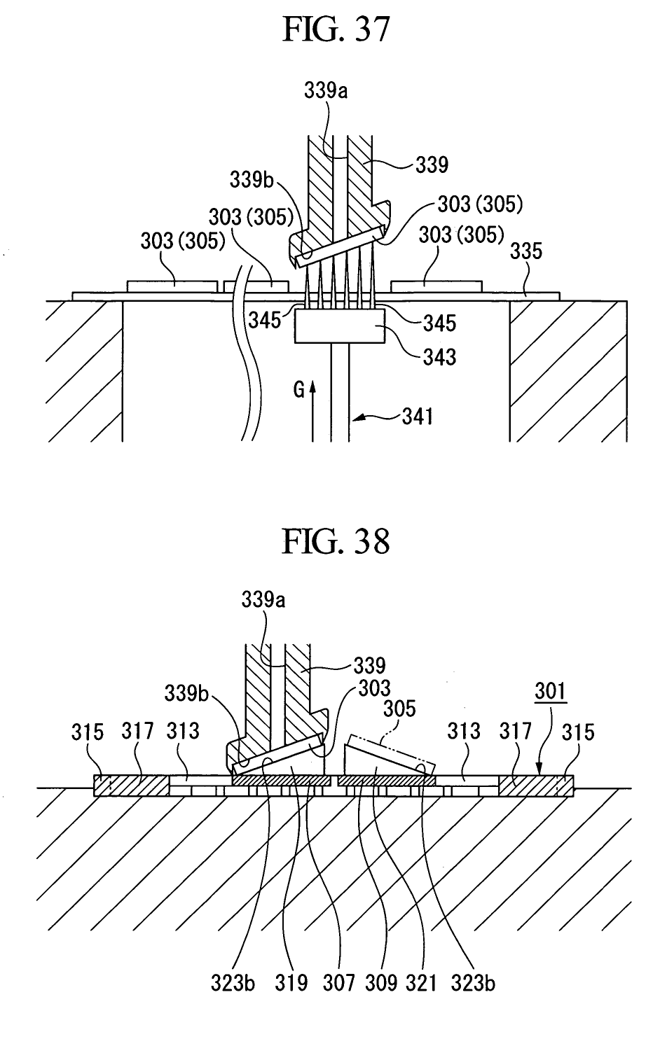

Thereafter, as shown in FIG. 38, the collet 339 holding the magnetic sensor chip 303 (or 305) by air suction is moved toward and above the slope 323b of the inclination member 319 (or 321); then, when the magnetic sensor chip 303 (or 305) is brought into contact with the slope 323b, the collet 339 stops the air suction using the suction hole 339a; hence, the magnetic sensor chip 303 (or 305) is mounted on the slope 323b. Thus, the chip mounting step is completed.

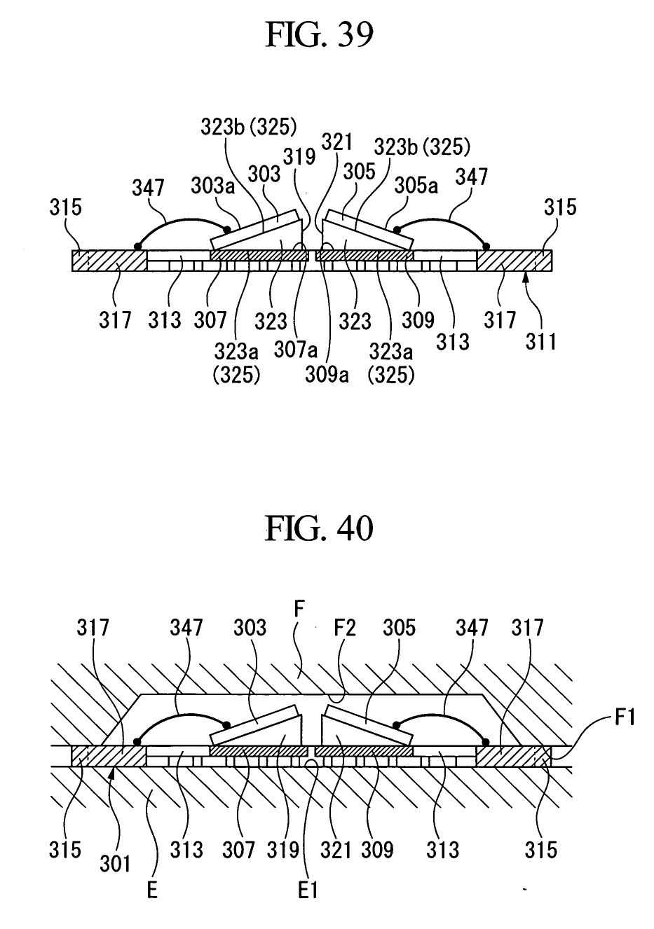

In the adhesion step, after completion of the chip mounting step, the stages 307 and 309 are heated using a heater (not shown) in a stage heating step. In the heating step, as shown in FIG. 39, the prescribed portions of the adhesive thin films 325 adhered to the bottoms 323a of the wedge base members 323 of the inclination members 319 and 321 are heated by way of the surfaces 307a and 309a of the stages 307 and 309 being heated, and the other portions of the adhesive thin films 325 adhered to the slopes 323b of the wedge base members 323 for mounting the magnetic sensor chips 303 and 305 are heated as well by way of the stages 307 and 309 being heated; hence, the adhesive thin films 325 are entirely heated and thus hardened. This allows the magnetic sensor chips 303 and 305 and the stages 307 and 309 to be respectively adhered to the slopes and bottoms of the inclination members 319 and 321.

Due to the aforementioned adhesion step, the magnetic sensor chips 303 and 305 are firmly adhered onto the stages 307 and 309.

After completion of the adhesion step, wire bonding is performed using wires 347, which are laid between the leads 317 and the bonding pads formed on surfaces 303a and 305a of the magnetic sensor chips 303 and 305, thus establishing electric connections between the leads 317 and the magnetic sensor chips 303 and 305 in a wiring step.

After completion of the wiring step, as shown in FIG. 40, the lead frame 301 is vertically held between a pair of metal molds E and F. The lower metal mold E has a planar surface E1 on which the rectangular frame portion 315 and the leads 317 are mounted; and the upper metal mold F has a recess F2 hollowed from a surface F1 thereof. When the rectangular frame portion 315 is held between the planar surface E1 of the lower metal mold E and the surface F1 of the upper metal mold F, all the magnetic sensor chips 303 and 305 and the inclination members 319 and 321 are completely stored inside of the recess F2.

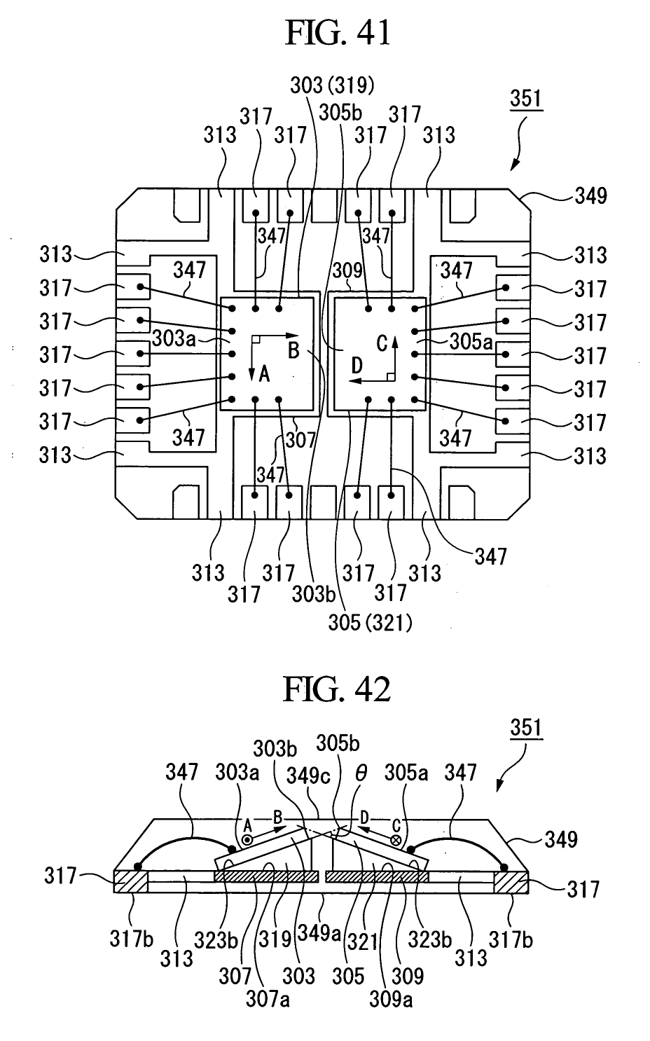

Then, a melted resin is injected into a space defined between the planar surface E1 of the lower metal mold E and the recess F2 of the upper metal mold F so as to form a resin mold section 349 (i.e., a package), in which all the magnetic sensor chips 303 and 305, the inclination members 319 and 321, the stages 307 and 309, the interconnection leads 313, and the leads 317 are embedded and integrally fixed together, in a molding step. Due to the molding step, as shown in FIGS. 41 and 42, the magnetic sensor chips 303 and 305 are precisely inclined by prescribed inclination angles with respect to the rectangular frame portion 315 and are fixed inside of the resin mold section 349.

Lastly, the rectangular frame portion 315 is subjected to cutting so as to individually separate the interconnection leads 313 and the leads 317. Thus, a magnetic sensor 351 is completely manufactured.

The resin mold section 349 of the magnetic sensor 351 has a rectangular shape in a plan view similar to the aforementioned rectangular frame portion 315. The leads 317 are electrically connected to the magnetic sensor chips 303 and 305 via the metal wires 347. In addition, backsides 317b of the leads 317 are exposed to a lower surface 349a of the resin mold section 349.

The magnetic sensor chips 303 and 305 are embedded inside of the resin mold section 349 and are respectively inclined with respect to the lower surface 349a of the resin mold section 349. Terminal ends 303b and 305b of the magnetic sensor chips 303 and 305 adjoining opposite to each other are directed upwards toward an upper surface 349c of the resin mold section 349; and the surfaces 303a and 305a of the magnetic sensor chips 303 and 305 are mutually inclined with each other by an acute angle θ therebetween, which is formed between the slopes 323b of the inclination members 319 and 321.

The magnetic sensor chip 303 is sensitive to components of magnetism lying in two directions of an external magnetic field, i.e., directions A and B, which cross at a right angle along the surface 303a thereof.

The magnetic sensor chip 305 is sensitive to components of magnetism lying in two directions of an external magnetic field, i.e., directions C and D, which cross at a right angle along the surface 305a thereof.

The directions A and C are reverse to each other and perpendicular to the coupling direction of the magnetic sensor chips 303 and 305. The directions B and D are reverse to each other and are parallel with the coupling direction of the magnetic sensor chips 303 and 305.

An A-B plane defined by the directions A and B along the surface 303a of the magnetic sensor chip 303 crosses a C-D plane defined by the directions C and D along the surface 305a of the magnetic sensor chip 305 by an acute angle θ therebetween.

The angle θ formed between the A-B plane and the C-D plane is greater than 0° and less than 90°. Theoretically, it is possible to detect bearings of geomagnetism in a three-dimensional space when the angle θ is greater than 0°. In order to secure a minimum sensitivity for detecting components of geomagnetic vectors perpendicular to the A-B plane or the C-D plane and to calculate them with a small error, it is preferable that the angle θ be greater than 20°. In order to further reduce error in calculation, it is preferable that the angle θ be greater than 30°.

For example, the magnetic sensor 351 is installed in a substrate of a portable terminal device (not shown), in which bearings of geomagnetism are displayed on a display panel.

According to the manufacturing method for the magnetic sensor 351, the magnetic sensor chips 303 and 305 are adhered to the surfaces 307a and 309a of the stages 307 and 309 via the inclination members 319 and 321 having wedge shapes; hence, it is possible to reliably incline the magnetic sensor chips 303 and 305 with respect to the surface 307a and 309a of the stages 307 and 309, and it is possible to reliably set prescribed inclination angles to the magnetic sensor chips 303 and 305 respectively. In other words, it is possible to improve the precision for setting the prescribed inclination angles to the magnetic sensor chips 303 and 305; hence, the magnetic sensor 351 is capable of precisely detecting bearings and acceleration in a three-dimensional space.

As described above, it is unnecessary to include a step for deforming the lead frame 301 in order to secure the magnetic sensor chips 303 and 305 being inclined with respect to the rectangular frame portion 315. This further improves the efficiency in manufacturing the magnetic sensor 351.

The inclination members 319 and 321 are constituted by the wedge base members 323, and the adhesive thin films 325 formed to cover the bottoms 323a and the slopes 323b of the wedge base members 323. Herein, the wedge base members 323 are composed of hard materials that are not deformed by heating in the stage heating step; hence, they can be stabilized in shaping. This further improves the precision for setting the prescribed inclination angles to the magnetic sensor chips 303 and 305, which are mounted on the stages 307 and 309 via the inclination members 319 and 321.

In addition, the magnetic sensor 351 can be easily manufactured by sequentially arranging the inclination members 319 and 321 and the magnetic sensor chips 303 and 305 on the surfaces 307a and 309a of the stages 307 and 309.

The stage heating step is performed after completion of the chip mounting step; hence, it is possible to simultaneously heat both the adhesive thin films 325 respectively brought into contact with the magnetic sensor chips 303 and 305 and the stages 307 and 309 at the same timing. This allows the magnetic sensor chips 303 and 305 and the stages 307 and 309 to be simultaneously adhered to the inclination members 319 and 321; hence, it is possible to improve the efficiency in manufacturing the magnetic sensor 351.

When the magnetic sensor chips 303 and 305 are transported to and mounted on the slopes 323b of the inclination members 319 and 321, the collet 339 is used to hold the magnetic sensor chips 303 and 305 so as to be substantially parallel to the slopes 323b. This controls the magnetic sensor chips 303 and 305 not to be deviated in positioning with respect to the slopes 323b. In other words, the magnetic sensor chips 303 and 305 can be arranged on the slopes 323b in a stable manner; hence, it is possible to improve the positioning accuracy of the magnetic sensor chips 303 and 305 with respect to the slopes 323b.

When the magnetic sensor chips 303 and 305 are attached to the collet 339, they are not necessarily arranged parallel to the slopes 323b of the inclination members 319 and 321 in the chip mounting step. It is simply required that when the magnetic sensor chips 303 and 305 are mounted on the slopes 323b, they be held substantially parallel to the slopes 323b of the inclination members 319 and 321.

The stage heating step, in which the adhesive thin films 325 of the inclination members 319 and 321 are heated and hardened so as to realize adhesion between the magnetic sensor chips 303 and 305, the stages 307 and 309, and the inclination members 319 and 321, is not necessarily performed after the chip mounting step. It is simply required that the adhesive thin films 325 of the inclination members 319 and 321 be heated and hardened, thus allowing the magnetic sensor chips 303 and 305 and the stages 307 and 309 to be adhered to the inclination members 319 and 321.

Therefore, the stage heating step can be performed subsequently to the chip mounting step. That is, the chip mounting step is performed in the heated condition of the stages 307 and 309; then, the adhesive thin films 325 brought into contact with the magnetic sensor chips 303 and 305 and the stages 307 and 309 are heated and hardened by use of heat of the stages 307 and 309.

The stage heating step can be performed subsequently to the member mounting step. That is, the member mounting step and chip mounting step are performed in the heated condition of the stages 307 and 309; then, the adhesive thin films 325 brought into contact with the magnetic sensor chips 303 and 305 and the stages 307 and 309 are heated and hardened by use of heat of the stages 307 and 309.

As described above, by heating the stages 307 and 309 in advance, the adhesive thin films 325 are heated and hardened just after the inclination members 319 and 321 are mounted on the surfaces 307a and 309a of the stages 307 and 309; hence, it is possible to rapidly establish adhesion between the magnetic sensor chips 303 and 305, the stages 307 and 309, and the inclination members 319 and 321. In addition, heating and hardening of the adhesive thin films 325 are performed by use of heat of the stages 307 and 309; hence, it is possible to easily and reliably establish adhesion between the magnetic sensor chips 303 and 305, the stages 307 and 309, and the inclination members 319 and 321.

The prescribed portions of the adhesive thin films 325 directly brought into contact with the magnetic sensor chips 303 and 305 are positioned apart from the surfaces 307a and 309a of the stages 307 and 309; hence, they may need a longer time in heating and hardening compared with the other portions of the adhesive thin films 325 directly brought into contact with the surfaces 307a and 309a of the stages 307 and 309. Therefore, even though the chip mounting step is performed after the member mounting step in the heated condition of the stages 307 and 309, it is possible to reliably mount the magnetic sensor chips 303 and 305 on the slopes 323b of the inclination members 319 and 321 before the prescribed portions of the adhesive thin films 325 directly brought into contact with the magnetic sensor chips 303 and 305 are hardened. In short, it is possible to firmly adhere the magnetic sensor chips 303 and 305 on the slopes 323b of the inclination members 319 and 321.

The chip mounting step is not necessarily performed after the member mounting step. For example, it is possible to perform the member mounting step, in which the inclination members 319 and 321 mounting the magnetic sensor chips 303 and 305 are mounted on the surfaces 307a and 309a of the stages 307 and 309, after the chip mounting step in which the magnetic sensor chips 303 and 305 are mounted on the slopes 323b of the inclination members 319 and 321.

In the above, the inclination members 319 and 321 mounting the magnetic sensor chips 303 and 305 are simply mounted on the surfaces 307a and 309a of the stages 307 and 309, which are held horizontally; thus, it is possible to realize the inclined condition of the magnetic sensor chips 303 and 305 with respect to the surfaces 307a and 309a of the stages 307 and 309. Thus, it is possible to easily produce the magnetic sensor 351.

Even when the member mounting step is performed after the chip mounting step, it is possible to perform the stage heating step, in which the magnetic sensor chips 303 and 305 and the stages 307 and 309 are adhered to the inclination members 319 and 321, after completion of the member mounting step.

In addition, the stage heating step can be performed subsequently to the member mounting step. That is, after the member mounting step is performed in the heated condition of the stages 307 and 309 such that the inclination members 319 and 321 mounting the magnetic sensor chips 303 and 305 are mounted on the surfaces 307a and 309a of the stages 307 and 309, the adhesive thin films 325 brought into contact with the magnetic sensor chips 303 and 305 and the stages 307 and 309 are heated and hardened by use of heat of the stages 307 and 309.

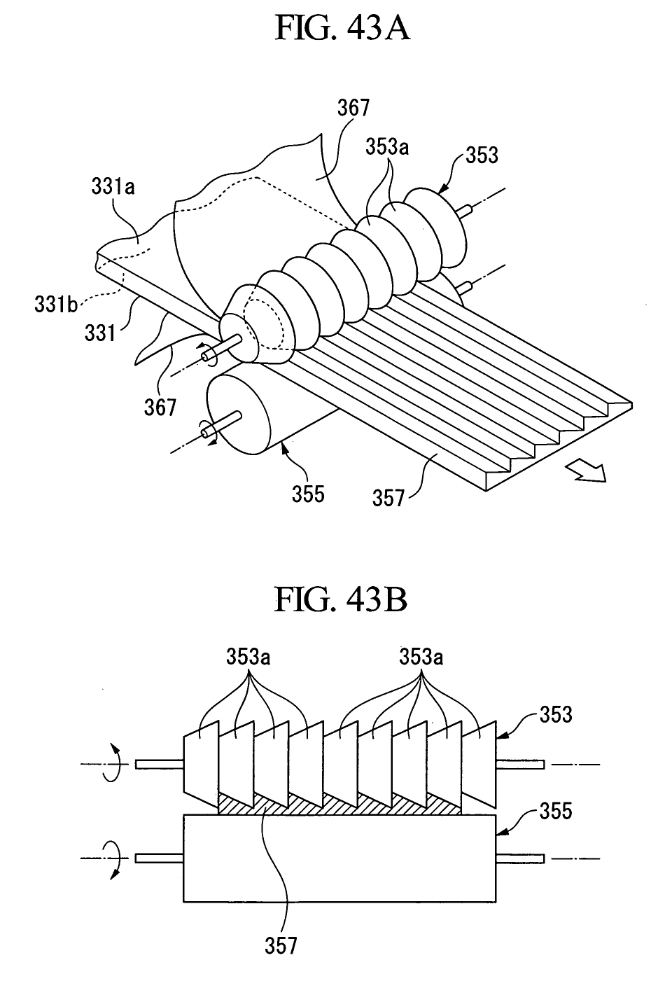

The inclination members 319 and 321 are not necessarily formed by way of the extrusion molding. For example, they can be formed by way of rolling. That is, as shown in FIGS. 43A and 43B, a resin material 331 is subjected to rolling using rollers 353 and 355, thus producing a molded member 357 having a saw-toothed shape. The molded member 357 is divided into pieces so as to produce the inclination members 319 and 321. The saw-toothed shape of the molded member 357 is formed in conformity with plural bevel wheels 353a formed on the roller 353.

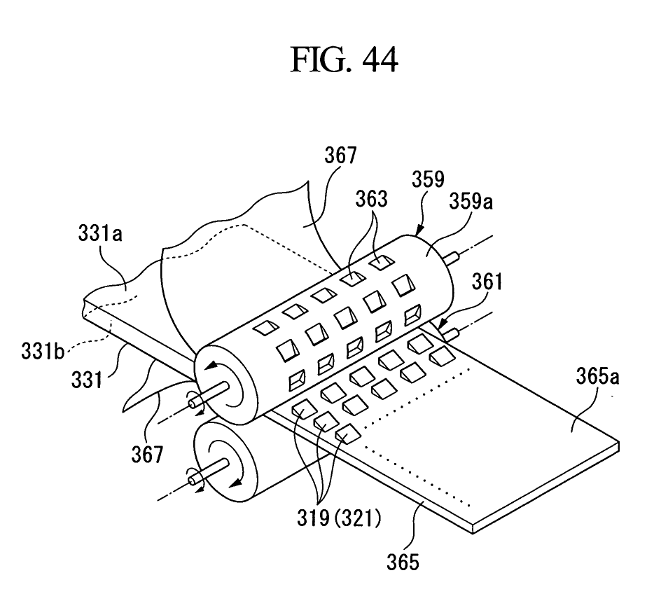

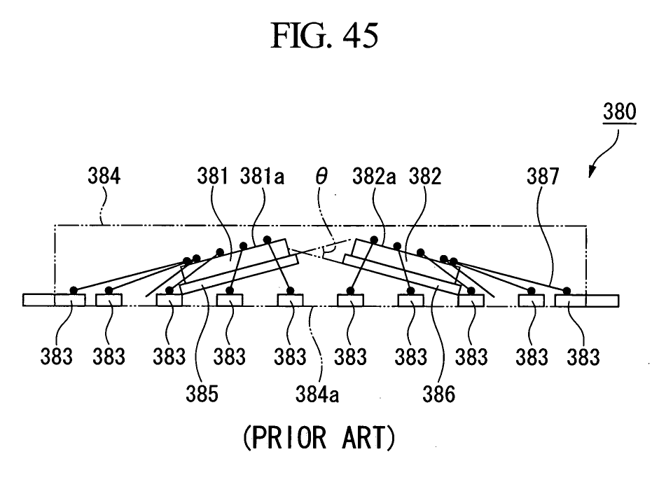

Alternatively, the inclination members 319 and 321 can be formed by way of rolling using rollers 359 and 361 shown in FIG. 44, for example. Herein, a plurality of cavities 363 for molding the inclination members 319 and 321 are formed in an outer peripheral surface 359a of the roller 359. By use of the roller 359, the inclination members 319 and 321 are shaped in conformity with the shapes of the cavities 363. In order to form the inclination members 319 and 321 having wedge shapes whose heights are set to 400 μm on a surface 365a of the molded member 365 whose thickness is 100 μm, for example, it is preferable that the thickness of the resin material 331 subjected to rolling be set to 500 μm.

When the inclination members 319 and 321 are formed by way of rolling using the rollers 353 and 355 or the rollers 359 and 361, adhesive films (or adhesive layers) 367 are attached to a surface 331a and a backside 331b of the resin material 331 in advance; hence, it is possible to improve the efficiency of producing the inclination members 319 and 321.

The aforementioned wedge base member 323 and the adhesive thin film 325 have insulation in the present embodiment, which is not a limitation. Basically, it is simply required that electrical insulation be secured between the magnetic sensor chips 303 and 305 and the stages 307 and 309. In other words, it is required that at least one of the wedge base member 323 and the adhesive thin film 325 has adhesion. In this case, the wedge base member 323 can be composed of a metal material, for example. The wedge base member 323 composed of a metal material has a high heat-dissipation ability compared with the wedge base member 323 composed of a resin material. This may easily prevent the magnetic sensor chips 303 and 305 from being excessively heated. When the wedge base member 323 is composed of a metal material, it is preferable that the adhesive thin film 325 has adhesion.

The adhesive thin film 325 is not necessarily attached to the bottom 323a and the slope 323b of the wedge base member 323 included in each of the inclination members 319 and 321. It is simply required that an adhesive layer be formed to establish mutual adhesion with the wedge base member 323. For example, an adhesive layer composed of silver paste can be applied to the bottom 323a and the slope 323b of the wedge base member 323. Alternatively, an adhesive gas can be sprayed onto the bottom 323a and the slope 323b of the wedge base member 323 so as to form an adhesive layer.

Each of the inclination members 319 and 321 is not necessarily formed using the wedge base member 323 and the adhesive layer formed on the bottom 323a and the slope 323b. For example, it can be formed using a specific member having an adhesive property.

It is described before that all the magnetic sensor chips 303 and 305, the inclination members 319 and 321, the stages 307 and 309, and the leads 317 are integrally fixed together in the resin mold section 349 in the present embodiment, which is not a limitation. For example, they can be stored inside of a hollow box-like member (i.e., a package), in which they are integrally fixed together.

The frame 311 of the lead frame 301 does not necessarily include the rectangular frame portion 315 having a rectangular shape in a plan view. Basically, it is simply required that the frame 311 has a frame portion allowing the leads 317 to project inwardly therefrom. For example, this frame portion can be formed in a circular shape in a plan view.

Each of the stages 307 and 309 is not necessarily formed in a rectangular shape in a plan view. Basically, it is simply required that the stages 307 and 309 be shaped to allow the magnetic sensor chips 303 and 305 to be adhered onto the surfaces 307a and 309a thereof. For example, each of the stages 307 and 309 can be formed in a circular shape or an elliptical shape in a plan view. Alternatively, it has through holes running through in the thickness direction thereof; or it is formed in a mesh-like shape.

Each of the stages 307 and 309 is not necessarily formed to mount a single magnetic chip (303 or 305) and a single inclination member (319 or 321) thereon. For example, it is possible to shape each stage to mount plural magnetic sensor chips and plural inclination members thereon.

The magnetic sensor 351 is not necessarily designed to detect the magnetism direction in a three-dimensional space. That is, it is possible to realize various types of physical quantity sensors for detecting bearings and directions in a three-dimensional space. For example, it is possible to realize an acceleration sensor having acceleration sensor chips for detecting the magnitude and direction of acceleration.

Lastly, the present invention is not necessarily limited to the aforementioned embodiments and the aforementioned variations, which are illustrative and not restrictive; hence, all changes and variations within the scope of the invention are intended to be embraced by the appended claims.

1. A manufacturing method for a physical quantity sensor that is produced using a lead frame having at least one stage for mounting a physical quantity sensor chip and a frame having a plurality of leads surrounding the stage, said manufacturing method including:
an adhesion step for adhering the physical quantity sensor chip on the stage that is inclined with respect to the frame;
a wiring step for performing wire bonding using wires so as to electrically connect the physical quantity sensor chip and the leads respectively by means of a bonding device; and
a positioning step for establishing prescribed positioning so as to allow the wires to be precisely bonded onto the physical quantity sensor chip and the leads by controlling a positional relationship between the lead frame and the bonding device.

2. A manufacturing method for a physical quantity sensor that is produced using a lead frame having at least one stage for mounting a physical quantity sensor chip and a frame having a plurality of leads surrounding the stage, said manufacturing method comprising the steps of:
adhering the physical quantity sensor chip on the stage that is inclined with respect to the frame; and
performing wire bonding using wires so as to electrically connect a surface of the physical quantity sensor chip, which is inclined with respect to the frame, and surfaces of the leads respectively,
wherein when the wire bonding is performed, the lead frame is pivotally rotated so as to locate the surface of the physical quantity sensor chip and the surfaces of the leads perpendicularly to a capillary for discharging the wires.

3. A bonding device applied to manufacturing of a physical quantity sensor, which is produced using a thin metal plate having a plurality of lead frames, each of which includes at least one stage for mounting a physical quantity sensor chip and a frame having a plurality of leads surrounding the stage, said bonding device comprising:
a base;
an instrument that is equipped with the base and pivotally rotates about a reference axial line, which is laid in parallel with the base, the instrument supporting the thin metal plate so as to hold the stage being inclined with respect to the frame; and
a capillary for performing wire bonding using wires so as to electrically connect a surface of the physical quantity sensor chip and surfaces of the leads respectively,
wherein the capillary is arranged opposite to the surface of the base with a prescribed angle therebetween,
and wherein when the instrument pivotally rotates, the surface of the physical quantity sensor chip and the surfaces of the leads are respectively located perpendicularly to the capillary.

4. A manufacturing method for a physical quantity sensor, comprising the steps of:
providing a lead frame having at least one stage for mounting a physical quantity sensor and a frame having a plurality of leads surrounding the stage;
inclining the stage with respect to the frame;
adhering the physical quantity sensor chip onto the stage; and
establishing electric connections using wires between a surface of the physical quantity sensor, which is inclined with respect to the frame, and surfaces of the leads respectively in accordance with a wedge bonding method,
wherein a wedge tool is positioned in parallel with the surface of the physical quantity sensor chip and the surfaces of the leads respectively so that the wires are held between the surface of the physical quantity sensor chip and the surfaces of the leads respectively.

5. A bonding device for establishing electric connections using wires in accordance with a wedge bonding method with respect to a physical quantity sensor which is produced using a lead frame having at least one stage for mounting a physical quantity sensor chip and a frame having a plurality of leads surrounding the stage, said bonding device comprising:
a base for mounting the lead frame; and
a wedge tool that can be moved relative to the base and that supplies the wires for establishing electric connections between a surface of the physical quantity sensor chip inclined with respect to the frame and surfaces of the leads respectively,
wherein the wedge tool has a first planar surface, which is formed in parallel with the surfaces of the leads so as to hold one ends of the wires therebetween, and a second planar surface, which is formed in parallel with the surface of the physical quantity sensor chip so as to hold other ends of the wires therebetween.

6. A bonding device according to claim 5, wherein the first planar surface and the second planar surface of the wedge tool are partially recessed to form guide channels for guiding the wires therein, and wherein the guide channels are elongated along the first planar surface and the second planar surface respectively.

7. A bonding device according to claim 6, wherein the wedge tool is moved in a longitudinal direction of the guide channels in proximity to the surface of the physical quantity sensor chip and the surfaces of the leads respectively.

8. A manufacturing method for a physical quantity sensor according to claim 1 further including:
a preparation step for providing the lead frame further including a plurality of interconnection leads, each including a shape memory alloy, for interconnecting the stage and the frame together;
a first heating step for heating the interconnection leads to be deformed at a restoration temperature of the shape memory alloy, thus allowing the stage to be inclined with respect to the frame by a prescribed angle; and
a second heating step, after the adhesion step and the wiring step, for heating the interconnection leads again at the restoration temperature of the shape memory alloy, thus inclining the stage by the prescribed angle with respect to the frame.

9. The manufacturing method for a physical quantity sensor according to claim 8, further including a deformation step for subjecting the interconnection leads to plastic deformation by way of press working so as to locate the stage planar to the frame after the stage is once inclined by heating and before the physical quantity sensor chip is adhered onto the stage.

10. A lead frame, which is produced using a thin metal plate, comprising:
at least one stage;
a frame having a plurality of leads surrounding the stage; and
a plurality of interconnection leads for interconnecting the stage and the frame together, wherein each of the interconnection leads includes a shape memory alloy, which is deformed by heating.

11. A lead frame according to claim 10, wherein a shape memory alloy member is attached to each of the interconnection leads.

12. A physical quantity sensor comprising:
at least one stage;
at least one physical quantity sensor chip;
a plurality of leads that are arranged to surround the stage and that are electrically connected to the physical quantity sensor chip;
at least one inclination member having a wedge shape, which is adhered onto a surface of the stage, and on which the physical quantity sensor chip is adhered; and
a package for integrally fixing the stage, the physical quantity sensor chip, the inclination member, and the leads therein.

13. A physical quantity sensor according to claim 12, wherein the inclination member is formed using a wedge base member in which an adhesion layer is formed to cover a bottom and a slope thereof.

14. A manufacturing method for a physical quantity sensor according to claim 1 further including:
a preparation step for providing the lead frame further including a plurality of interconnection leads for interconnecting the stage and the frame together; and
an inclination step, associated with the adhesion step before the wiring step, for adhering the physical quantity sensor chip onto the stage via an inclination member having a wedge shape.

15. The manufacturing method for a physical quantity sensor according to claim 14, further including:
a chip mounting step for mounting the physical quantity sensor chip on a slope of the inclination member; and
a member mounting step for mounting the inclination member mounting the physical quantity sensor chip onto a surface of the stage.

16. The manufacturing method for a physical quantity sensor according to claim 14, further including:
a member mounting step for mounting the inclination member onto a surface of the stage; and
a chip mounting step for mounting the physical quantity sensor chip on a slope of the inclination member, which is already mounted on the surface of the stage.

17. The manufacturing method for a physical quantity sensor according to claim 15, wherein the inclination member has an adhesive layer having a thermosetting property, which is adhered to the physical quantity sensor chip and the stage respectively, and wherein the adhesive layer is heated and hardened after the inclination member mounting the physical quantity sensor chip is mounted on the surface of the stage.

18. The manufacturing method for a physical quantity sensor according to claim 15, wherein the inclination member has an adhesion layer having a thermosetting property, which is adhered to the physical quantity sensor chip and the stage respectively, and wherein the inclination member mounting the physical quantity sensor chip is mounted on the surface of the stage which is heated in advance, so that the adhesive layer is heated and hardened by use of heat of the stage.

19. The manufacturing method for a physical quantity sensor according to claim 16, wherein before the physical quantity sensor chip is mounted on a slope of the inclination member, the physical quantity sensor chip is inclined in advance to be parallel to the slope of the inclination member.

20. The manufacturing method for a physical quantity sensor according to claim 19, wherein the physical quantity sensor chip is attached to a collet by way of air suction and is transported toward the slope of the inclination member in such a way that the physical quantity sensor chip is inclined to be parallel to the slope of the inclination member.

21. The manufacturing method for a physical quantity sensor according to claim 16, wherein the inclination member has an adhesive layer having a thermosetting property, which is adhered to the physical quantity sensor chip and the stage respectively, and wherein t he adhesive layer is heated and hardened after the inclination member mounting the physical quantity sensor chip is mounted on the surface of the stage.

22. The manufacturing method for a physical quantity sensor according to claim 16, wherein the inclination member has an adhesion layer having a thermosetting property, which is adhered to the physical quantity sensor chip and the stage respectively, and wherein the inclination member mounting the physical quantity sensor chip is mounted on the surface of the stage which is heated in advance, so that the adhesive layer is heated and hardened by use of heat of the stage.
